(19) United States
(12) Patent Application Publication
(10) Pub. No.: US 2026/0338851 A1
(43) Pub. Date: Oct. 29, 2026

(54) SYSTEMS AND METHODS FOR DETERMINING TURN-ON VOLTAGE OF TRANSISTORS

(71) Applicant: Conductor Quantum, Inc., San Francisco, CA (US)

(72) Inventors: Joel Kieron PENDLETON, San Francisco, CA (US); Brandon SEVERIN, San Francisco, CA (US)

(73) Assignee: Conductor Quantum, Inc., San Francisco, CA (US)

(21) Appl. No.: 19/654,696

(22) Filed: Apr. 22, 2026

Related U.S. Application Data
(60) Provisional application No. 63/792,801, filed on Apr. 22, 2025.

(51) Int. Cl. G01R 31/26; G06N 20/00

(52) U.S. Cl. CPC G01R 31/2601; G06N 20/00

(57) ABSTRACT

A method for determining a turn-on voltage for a transistor includes applying a range of input voltages to a transistor and measuring resulting currents, inputting the resulting currents into an on-state detection machine learning model trained to determine whether the transistor entered an on-state based on the resulting currents, wherein the on-state detection machine learning model outputs a classification indicating whether the transistor entered the on-state, if the classification indicates the transistor entered the on-state, inputting the resulting currents into a turn-on region finding machine learning model trained to determine a current turn-on region of the inputted resulting currents, wherein the turn-on region finding machine learning model outputs a current turn-on region of the transistor, and determining the turn-on voltage for the transistor based on the outputted current turn-on region of the transistor by identifying the turn-on voltage within the outputted current turn-on region.

### CROSS-REFERENCE TO RELATED APPLICATIONS

This application claims the benefit of U.S. Provisional Application No. 63/792,801, filed Apr. 22, 2025, the entire contents of which are incorporated herein by reference.

### FIELD

This application relates generally to transistors, and more specifically to systems and methods for determining whether a transistor enters an on-state and determining a turn-on voltage of a transistor that enters the on-state.

### BACKGROUND

Transistors and transistor like devices are fundamental building blocks of modern electronics and have recently emerged as useful devices of quantum applications, such as quantum computing and quantum sensing. To use a transistor, a voltage is applied across the transistor, and depending on the magnitude of the applied voltage, current may flow through the transistor. The magnitude of the applied voltage that marks the transition of the transistor from an off-state (e.g., current does not flow) to an on-state (e.g., current does flow) is commonly referred to as the turn-on voltage.

Conventionally, the turn-on voltage is estimated by manually thresholding current-voltage data into the off-state and the on-state using a pre-defined current threshold or pre-defined slope change threshold, such that the voltage associated with the pre-defined current threshold or pre-defined slope change threshold is the turn-on voltage. However, such conventional methods often struggle with transistor-to-transistor variability, measurement noise, or temperature fluctuations, which diminishes the accuracy of the estimated turn-on voltage, and thus diminishes the reliability of the transistor for use in electronic devices. In addition to designating the operating conditions of the transistor, the turn-on voltage is also used to characterize a transistor's performance, such as its switching speed and power consumption. As such, an accurate determination of the turn-on voltage of the transistors is relevant not only for the practical use of the transistors in modern electronics, but for the development and manufacture of transistors (e.g., quality assurance, design, fabrication, etc.).

### SUMMARY

Described herein are systems and methods for determining a turn-on voltage for a transistor using two machine learning models. In the described systems and methods, a range of voltages are applied to a transistor (e.g., such as applied to a gate terminal of a transistor) while current from the transistor is monitored. The measured currents (or the measured currents and the range of applied voltages) may then be inputted into a first machine learning model trained to identify whether the transistor turned on while the range of voltages were applied. If the transistor turned on, the measured currents may be inputted into a second machine learning model trained to determine a region of the measured currents at which the transistor first turned on (e.g., a current turn-on region). The turn-on voltage for the transistor may then be determined within the region identified by the second machine learning model. The two machine learning model approach provides an efficient and accurate determination of the turn-on voltage for the transistor. For instance, the two machine learning model approach may be efficient as it preserves computational resources by not determining the current turn-on region for transistors that do not turn on. The two machine learning model approach may also make failure analysis (e.g., debugging) easier. For instance, failure in determining the turn-on voltage for the transistor can easily and clearly be attributed to either an inaccurate identification that the transistor turned on or an inaccurate identification of the current turn-on region.

According to an aspect, systems and methods identify whether a transistor entered an on-state and determine a turn-on voltage for the transistor that entered the on-state. Identifying whether the transistor enters the on-state may include: 1) testing the transistor by applying the range of voltages and measuring resulting currents, 2) inputting the measured currents into an on-state detection machine learning model trained to determine whether the transistor entered the on-state, and 3) receiving a classification output from the on-state detection machine learning model indicating whether the transistor entered the on-state. If the classification output of the on-state detection machine learning model indicates the transistor entered the on-state, the turn-on voltage for the transistor may be determined by: 1) inputting the measured currents into a turn-on region finding machine learning model trained to determine a current turn-on region of the inputted measured currents, 2) receiving the current turn-on region from the turn-on region finding machine learning model, and 3) identifying the turn-on voltage within the outputted current turn-on region.

The transistor may be tested by applying the range of voltages to a first terminal of the transistor using a voltage system, and in response to each voltage in the range of voltages, measuring a current, or a plurality of currents, from a second terminal of the transistor using a current system. The measured currents may be inputted into the on-state detection machine learning model configured to handle a variety of inputs including inputs with excessive noise, a reduced signal-to-noise ratio, or incomplete information. The on-state detection machine learning model may output the classification output, such as a binary label in which a first state of the binary label indicates the transistor entered the on-state and a second state of the binary label indicates the transistor did not enter the on-state. If the classification output indicates the transistor entered the on-state, the measured currents may be inputted into the turn-on region finding machine learning model similarly configured to handle a variety of inputs including inputs with excessive noise, a reduced signal-to-noise ratio, or incomplete information. The turn-on region finding machine learning model may output the current turn-on region for the transistor, which may be a portion of the inputted measured currents at which the inputted measured currents first exhibit a linear-like increase in magnitude. The turn-on voltage may be determined by identifying the turn-on voltage within the current turn-on region. For instance, the turn-on voltage within the current turn-on region may be identified by correlating the range of applied voltages to the current turn-on region and calculating an average voltage or a midpoint voltage of the applied voltages correlated to the current turn-on region.

According to some embodiments, a method for determining a turn-on voltage for a transistor is provided, the method comprising applying a range of input voltages to a transistor and measuring resulting currents, inputting the resulting currents into an on-state detection machine learning model trained to determine whether the transistor entered an on-state based on the resulting currents, wherein the on-state detection machine learning model outputs a classification indicating whether the transistor entered the on-state, if the classification indicates the transistor entered the on-state, inputting the resulting currents into a turn-on region finding machine learning model trained to determine a current turn-on region of the inputted resulting currents, wherein the turn-on region finding machine learning model outputs a current turn-on region of the transistor, and determining the turn-on voltage for the transistor based on the outputted current turn-on region of the transistor by identifying the turn-on voltage within the outputted current turn-on region.

In any of these embodiments, identifying the turn-on voltage within the outputted current turn-on region comprises correlating the outputted current turn-on region to the input voltages and determining an average voltage or midpoint voltage based on the input voltages correlated to the outputted current turn-on region. In any of these embodiments, the turn-on region finding machine learning model outputs an array of identifiers in accordance with the inputted resulting currents. In any of these embodiments, if the classification indicates the transistor did not enter the on-state, the resulting currents are not inputted into the turn-on region finding machine learning model and the turn-on voltage for the transistor is not determined.

In any of these embodiments, the transistor is a transistor like device. In any of these embodiments, the transistor is a metal oxide field-effect transistor (MOSFET), a field-effect transistor (FET), or a single-electron transistor (SET). In any of these embodiments, the classification from the on-state detection machine learning model is a binary label, wherein a first state of the binary label indicates the transistor entered the on-state and a second state of the binary label indicates the transistor did not enter the on-state.

In any of these embodiments, the method comprising training the on-state detection machine learning model, comprising generating one or more transistor models, inputting a range of labeled simulated voltages into the one or more transistor models and receiving labeled simulated currents from the one or more transistor models, and training the on-state detection machine learning model based on the labeled simulated currents. In any of these embodiments, the on-state detection machine learning model is further trained with labeled simulated voltages. In any of these embodiments, the labeled simulated currents indicate a simulated transistor of the one or more transistor models entered the on-state or the labeled simulated currents indicate the simulated transistor of the one or more transistor models did not enter the on-state.

In any of these embodiments, the method comprising training the turn-on region finding machine learning model, comprising labeling the current turn-on region of the labeled simulated currents and training the turn-on region finding machine learning model based on the labeled simulated currents comprising the labeled current turn-on region. In any of these embodiments, labeling the current turn-on region of the labeled simulated currents comprises correlating each labeled simulated current of the labeled simulated currents to an identifier, wherein a first identifier represents the current turn-on region of the simulated transistor and a second identifier does not represent the current turn-on region of the simulated transistor.

According to some embodiments, a transistor system configured to turn on one or more transistors is provided, the system comprising one or more voltage systems configured to apply a range of input voltages to the one or more transistors and configured to apply a turn-on voltage to each transistor of the one or more transistors, one or more current systems configured to measure resulting currents from the one or more transistors, a control system, comprising one or more processors, configured to turn on each transistor of the one or more transistors using the turn-on voltage for each transistor, wherein the turn-on voltage for each transistor has been determined by applying a range of input voltages to a transistor and measuring resulting currents, inputting the resulting currents into an on-state detection machine learning model trained to determine whether the transistor entered an on-state based on the resulting currents, wherein the on-state detection machine learning model outputs a classification indicating whether the transistor entered the on-state, if the classification indicates the transistor entered the on-state, inputting the resulting currents into a turn-on region finding machine learning model trained to determine a current turn-on region of the inputted resulting currents, wherein the turn-on region finding machine learning model outputs a current turn-on region of the transistor, and determining the turn-on voltage for the transistor based on the outputted current turn-on region of the transistor by identifying the turn-on voltage within the outputted current turn-on region.

In any of these embodiments, the control system is further configured to control the one or more voltage systems to apply the range of input voltages to the one or more transistors and to apply the turn-on voltage to each transistor of the one or more transistors and control the one or more current systems to measure the resulting currents from the one or more transistors. In any of these embodiments, the transistor is a transistor like device.

According to some embodiments, a method for determining turn-on voltages for one or more transistor like devices of a quantum device is provided, the method comprising applying a range of input voltages to each transistor like device of the one or more transistor like devices and measuring resulting currents, inputting the resulting currents into an on-state detection machine learning model trained to determine whether each transistor like device of the one or more transistor like devices entered an on-state based on the resulting currents, wherein the on-state detection machine learning model outputs a classification indicating whether each transistor like device of the one or more transistor like devices entered the on-state, if the classification indicates one or more transistor like devices entered the on-state, inputting the resulting currents of each transistor like device of the one or more transistor like devices into a turn-on region finding machine learning model trained to determine a current turn-on region of the inputted resulting currents, wherein the turn-on region finding machine learning model outputs a current turn-on region of each transistor like device, and determining the turn-on voltage for each transistor like device of the one or more transistor like devices based on the outputted current turn-on region of each transistor like device by identifying the turn-on voltage within the outputted current turn-on region of each transistor like device.

### BRIEF DESCRIPTION OF THE DRAWINGS

The invention will now be described, by way of example only, with reference to the accompanying drawings, in which:

FIG. 1A illustrates a system for determining a turn-on voltage for a transistor, according to some embodiments.

FIG. 1B is a plot of simulated currents that can be measured from a transistor versus simulated applied voltages, according to some embodiments.

FIG. 1C is a plot of simulated currents that can be measured from a transistor and an array of identifiers outputted from a turn-on region finding machine learning model, according to some embodiments.

FIG. 2 illustrates a method of training an untrained on-state detection machine learning model with labeled simulated currents generated by one or more transistor models modeling behavior of simulated transistor(s), according to some embodiments.

FIG. 3A is a plot of simulated currents associated with a transistor that enters an on-state, according to some embodiments.

FIG. 3B is a plot of simulated currents associated with a transistor that does not enter an on-state, according to some embodiments.

FIG. 4 illustrates a method of training an untrained turn-on region finding machine learning model with labeled simulated currents that includes a labeled current turn-on region, according to some embodiments.

FIG. 5A is a plot of simulated currents associated with a transistor that entered an on-state overlaid with identifiers marking a current turn-on region of the simulated data, according to some embodiments.

FIG. 5B is a plot of simulated currents associated with a transistor that did not enter an on-state overlaid with identifiers not marking a current turn-on region of the simulated data, according to some embodiments.

FIG. 6 illustrates a method for determining a turn-on voltage of a transistor, according to some embodiments.

FIG. 7 illustrates a system for operating each transistor like device of one or more transistor like devices of a quantum device, according to some embodiments.

FIG. 8 illustrates a computing unit, according to some embodiments.

### DETAILED DESCRIPTION

Described herein are systems and methods for determining a turn-on voltage for a transistor using two machine learning models. A first machine learning model is an on-state detection machine learning model that may identify whether applying a range of voltages to the transistor eventually causes the transistor to turn on. For instance, the on-state detection machine learning model may attempt to identify features in data associated with the transistor (e.g., such as currents measured from the transistor) that are indicative of the transistor turning on (e.g., transistor entering an on-state). If the transistor is identified as turning on, the data associated with the transistor may be inputted into a second machine learning model. The second machine learning model is a turn-on region finding machine learning model that may determine a current turn-on region of the transistor data. The current turn-on region may be a portion of the transistor data that includes the features indicative of the transistor turning on (e.g., transistor entering an on-state). The turn-on voltage for the transistor may then be determined within the current turn-on region identified by the turn-on region finding machine learning model. For instance, the turn-on voltage may be determined by selecting the voltages in the range of applied voltages associated with the current turn-on region and calculating an average voltage or midpoint voltage from the selected voltages.

Identifying whether applying the range of voltages to the transistor eventually causes the transistor to turn on may include: 1) testing the transistor by applying the range of voltages to the transistor and measuring resulting currents, 2) inputting the measured currents, obtained from testing the transistor, into the on-state detection machine learning model trained to determine whether a transistor entered an on-state, and 3) receiving a classification output from the on-state detection machine learning model indicating whether the transistor entered the on-state.

The transistor may be tested by applying the range of voltages to a terminal (e.g., such as, a gate terminal) of the transistor using a voltage system. For each applied voltage in the range of applied voltages, a resulting current may be measured from another terminal (e.g., such as a drain terminal) of the transistor using a current system.

The measured currents may be inputted into the on-state detection machine learning model configured to determine whether the transistor entered the on-state based on the inputted measured currents. The on-state detection machine learning model may be configured to handle a variety of inputs including inputs with excessive noise, a reduced signal-to-noise ratio, incomplete information, etc. because the on-state detection machine learning model is trained using a broad input distribution (e.g., broad range of current values), a broad transistor parameter distribution, and/or data with various noise profiles. Training and validation data for the on-state detection machine learning model may be generated by one or more transistor models, such that the training and validation data either represents a transistor that entered the on-state or a transistor that did not enter the on-state (e.g., such as a randomly generated polynomial function). The on-state detection machine learning model may be trained using the training data and a supervised classification loss function. To ensure the on-state detection machine learning model generalizes, training the on-state detection machine learning model may further include regularization, early-stopping, and evaluation with the validation data. To determine whether the transistor entered the on-state, the on-state detection machine learning model may attempt to identify one or more features of the inputted measured currents indicative of a transistor that has entered an on-state, such as a linear-like increase in the magnitude of the inputted measured currents.

The on-state detection machine learning model may output a classification indicating whether the transistor entered the on-state (e.g., whether the inputted data indicates the transistor entered the on-state). The classification may be a binary label, such that a first state of the binary label indicates the transistor entered the on-state and a second state of the binary label indicates the transistor did not enter the on-state. In some embodiments, the classification may be a probability or a confidence score indicating a likelihood that the transistor entered the on-state.

The turn-on voltage of the transistor that entered the on-state may be determined by: 1) inputting the measured currents of the transistor into a turn-on region finding machine learning model configured to determine a current turn-on region based on the inputted measured currents, 2) receiving the current turn-on region from the turn-on region finding machine learning model, and 3) identifying the turn-on voltage within the current turn-on region.

If the classification output from the on-state detection machine learning model indicates the transistor entered the on-state, the measured currents associated with said transistor may be inputted into the turn-on region finding machine learning model. The current turn-on region of the inputted measured currents may be a portion of the inputted measured currents at which the inputted measured currents first exhibit a linear-like increase in its magnitude. The turn-on region finding machine learning model may similarly be configured to handle a variety of inputs (e.g., measured currents) including inputs with excessive noise, a reduced signal-to-noise ratio, incomplete information, etc. because the turn-on region finding machine learning model is trained using a broad input distribution, a broad transistor parameter distribution, and/or inputs with various noise profiles. Training and validation data for the turn-on region finding machine learning model may be generated by one or more transistor models, such that the training and validation data either includes a portion at which a magnitude of the data begins to increase in a linear-like manner or does not include a portion at which the magnitude of the data begins to increase in the linear-like manner. The turn-on region finding machine learning model may be trained using the training data and a semantic segmentation-based loss function (e.g., such as a cross-entropy loss function). To refine the performance of the turn-on region finding machine learning model, its training may further include cross-validation and hyperparameter tuning via the validation data.

The turn-on region finding machine learning model may output the current turn-on region of inputted measured currents of the transistor. For instance, the turn-on region finding machine learning model may output an array of identifiers that includes the current turn-on region. Each index of the array of identifiers may be associated with a value of the inputted measured currents and the length of the array may be the length of the inputted measured currents. A first identifier (e.g., such as a first binary digit) may indicate the associated value of the inputted measured currents represents the current turn-on region of the transistor. A second identifier (e.g., such as a second binary digit) may indicate the associated value of the inputted measured currents does not represent the current turn-on region of the transistor. For instance, the current turn-on region of the transistor may be a plurality of the first identifiers sequentially ordered in the array of identifiers.

The turn-on voltage may be identified within the current turn-on region by: 1) correlating the current turn-on region to an array of the voltages applied to the transistor during testing and 2) calculating an average or midpoint voltage of the voltages correlated to the current turn-on region. For instance, the indices associated with the plurality of first identifiers sequentially ordered in the array of identifies may be correlated to associated indices of the array of applied voltages. The turn-on voltage may then be determined by calculating an average voltage or a midpoint voltage of the applied voltages correlated to the current turn-on region.

According to an aspect, the turn-on voltage may be used to operate the transistor. For instance, applying a voltage of magnitude less than the turn-on voltage to the transistor (e.g., such as applying a voltage of magnitude less than the turn-on voltage to a gate terminal of the transistor) may turn the transistor off, and applying a voltage of magnitude greater than or equal to the turn-on voltage may turn the transistor on.

According to an aspect, a system configured to turn on one or more transistors includes one or more voltage systems, one or more current systems, and a control system. The one or more voltage systems may be configured to apply a range of voltages to a first terminal of each transistor of the one or more transistors and configured to apply a turn-on voltage to each transistor. The one or more current systems may be configured to measure currents, resulting from the applied voltages, from a second terminal of each transistor of the one or more transistors. The control system may be configured to turn on each transistor using the turn-on voltage of each transistor. The control system may also be configured to: 1) control the one or more voltage systems to apply the range of voltages to each transistor and to apply the turn-on voltage to each transistor, 2) control the one or more current systems to measure the resulting currents from each transistor, 3) control the on-state detection machine learning model to identify whether each transistor of the one or more transistors entered an on-state, 4) control the turn-on region finding machine learning model to determine a current turn-on region for each transistor that entered the on-state, and 5) determine the turn-on voltage for each transistor that entered the on-state by identifying the turn-on voltage within the current turn-on region of each transistor that entered the on-state.

According to an aspect, the systems and methods described herein determine a turn-on voltage for one or more transistor like devices of a quantum device. For instance, the systems and methods described herein may determine the turn-on voltage for each transistor like device of the one or more transistor like devices that is determined to enter an on-state. Using one or more voltage systems, the turn-on voltage for each transistor like device may be applied to the respective transistor like device such that subsequent systems and methods may be used to calibrate (e.g., tune) the transistor like device into an operable quantum dot. For instance, subsequent systems and methods may apply the turn-on voltage to each respective transistor like device (e.g., such as applying the turn-on voltage to one or more gate terminals of the transistor like device) to configure each transistor like device for pinch-off (e.g., S-shaped transition in a plot of measured current vs. applied voltage) measurements, Coulomb blockade oscillation (e.g., peaks also in a plot of measured current vs. applied voltage) measurements, or charge stability diagram measurements. As such, the one or more transistor like devices of the quantum device may be used in quantum applications, such as quantum computing and/or quantum sensing.

### Definitions

As used herein, the “turn-on voltage” means a minimum voltage, that when applied to the transistor (e.g., such as applied to a gate terminal of the transistor), allows meaningful current to flow through the transistor. The term turn-on voltage and threshold voltage may be used interchangeably.

As used herein, a “transistor” includes both classical transistors and transistor like devices used in quantum devices. “Transistor like devices” are devices composed of semiconductor material(s) that exhibit an off state characterized by no, or little, current flow and an on-state characterized by meaningful current flow (e.g., devices that exhibit turn-on behavior).

The following description sets forth exemplary systems, parameters, and the like. It should be recognized, however, that such description is not intended as a limitation on the scope of the present disclosure but is instead provided as a description of exemplary embodiments.

Although the following description uses terms “first,” “second,” etc. to describe various elements, these elements should not be limited by the terms. These terms are only used to distinguish one element from another. For example, a first graphical representation could be termed a second graphical representation, and, similarly, a second graphical representation could be termed a first graphical representation, without departing from the scope of the various described embodiments. The first graphical representation and the second graphical representation are both graphical representations, but they are not the same graphical representation.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

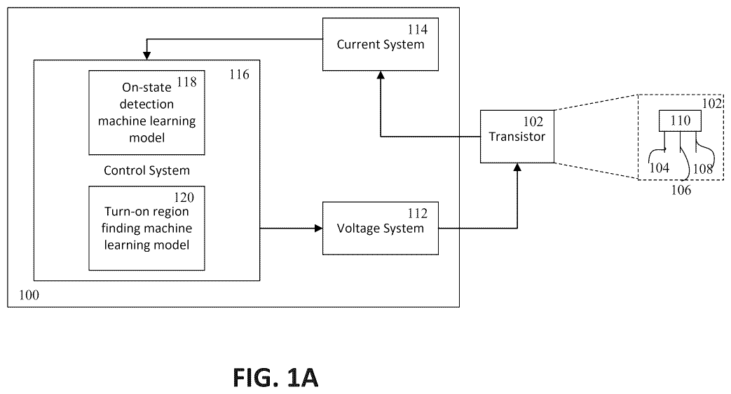

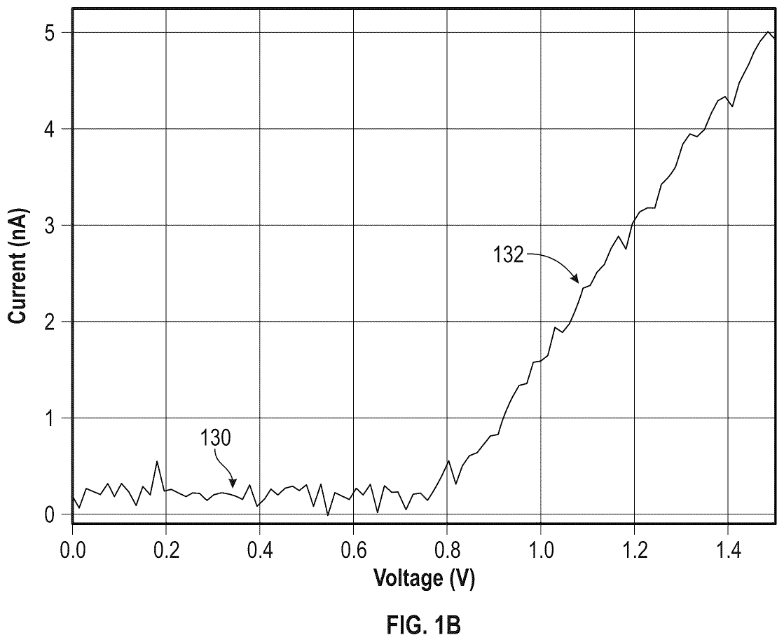

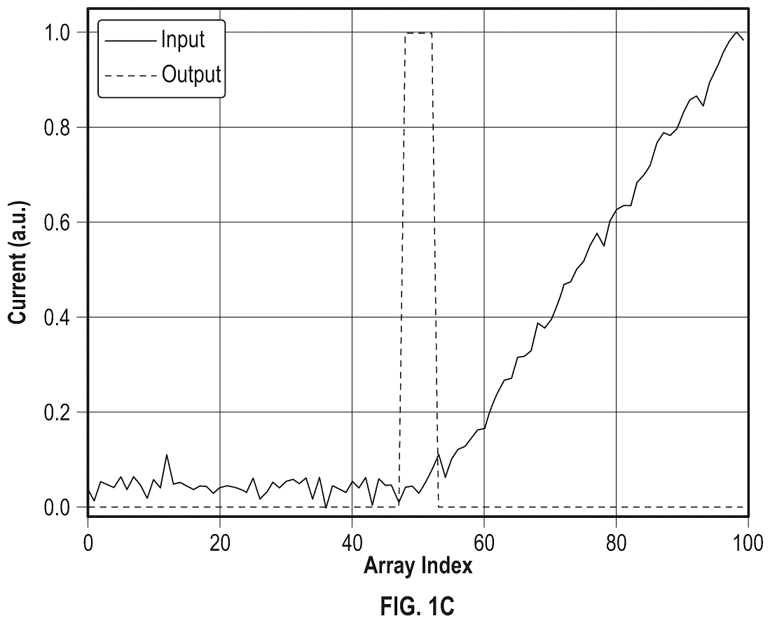

A transistor may be operated by modulating a voltage applied to the transistor. For instance, applying a voltage to the transistor of magnitude less than the transistor's turn-on voltage turns the transistor off (e.g., hinders current flow such that the transistor has negligible conduction). Conversely, applying a voltage to the transistor of magnitude greater than or equal to the transistor's turn-on voltage turns the transistor on, thus allowing current to flow through and from the transistor (e.g., allows current flow such that the transistor has some or significant conduction). As such, accurate determination of the turn-on voltage for a transistor may be relevant for operating said transistor. FIG. 1A illustrates an exemplary system 100 configured to determine a turn-on voltage for a transistor 102.

### Transistor

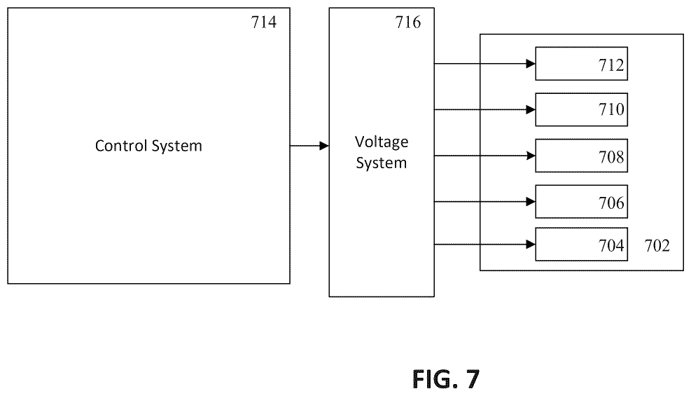

The transistor 102 may be any transistor, such as a, a metal oxide field-effect transistor (MOSFET) (e.g., N-channel MOSFET or P-channel MOSFET), a field-effect transistor (FET), a single-electron transistor (SET), or a junction field effect transistor (JFET) (e.g., N-channel JFET or P-channel JFET). The transistor 102 may have a first terminal 104 (e.g., drain terminal (or source terminal)), a second terminal 106 (e.g., gate terminal), and a third terminal 108 (source terminal (or drain terminal)) electrically connected to a semiconductor material, or a combination of semiconductor materials, within a package 110. The package 110 may be composed of any material (or combination of materials) configured to dissipate heat, protect the semiconductor material (or combination of semiconductor materials) of the transistor 102 from the environment, and/or to mechanically support the semiconductor material (or combination of semiconductor materials) of the transistor 102 and the first 104, second 106, and third 108 terminals. For instance, the package 110 may be composed of plastic, ceramic, metal, and/or glass. The semiconductor material, or combination of semiconductor materials, of the transistor 102 may be any semiconductor materials, such as bilayer graphene, Group-IV semiconductor materials (e.g., germanium, silicon, germanium/silicon between two layers of silicon-germanium, etc.), doped Group-IV semiconductor materials (e.g., doped germanium, doped silicon, etc.), and/or Group-III and Group-V semiconductor materials (e.g., gallium arsenide, indium gallium arsenide, etc.). In some embodiments, the transistor 102 is a component of an integrated circuit or a quantum device, such as quantum device 702 of FIG. 7.

In some embodiments, the transistor 102 is a transistor like device. The transistor like device may be calibrated (e.g., tuned) using subsequent systems and methods to be a quantum dot that may be used in quantum applications, such as quantum computing and/or quantum sensing. For instance, once the turn-on voltage for the transistor like device is determined using the systems and methods described herein, a voltage greater than or equal to the turn-on voltage may be applied to the transistor like device and subsequent systems and methods (e.g., such as pinch-off measurements, Coulomb blockage oscillation measurements, or charge stability diagram measurements) may tune the transistor like device into a quantum dot. The transistor like device may be composed of any semiconductor material, or combination of semiconductor materials, disclosed herein.

In some embodiments, the transistor 102 has a plurality of second terminals 106 (e.g., a plurality of gate terminals) between the first terminal 104 and the third terminal 108. For instance, the transistor 102 may have a source terminal (e.g., such as the first terminal 104), a first gate terminal (e.g., such as the second terminal 106), a second gate terminal (e.g., such as the second terminal 106), and a drain terminal (e.g., such as the third terminal 108). In some embodiments, the transistor 102 has any integer number of second terminals 106 (e.g., gate terminals) between the first terminal 104 and the third terminal 108 in a range of 1-5. In some embodiments, the transistor 102 has at least 1 second terminal 106, at least 2 second terminals 106, at least 3 second terminals 106, at least 4 second terminals 106, or at least 5 second terminals 106 between the first terminal 104 and the third terminal 108. In some embodiments, the transistor 102 has at most 5 second terminals 106, at most 4 second terminals 106, at most 3 second terminals 106, at most 2 second terminals 106, or 1 second terminal 106 between the first terminal 104 and the third terminal 108. As such, the transistor 102 has any integer number of total terminals that include the first terminal 104, the one or more second terminals 106, and the third terminal 108 in a range of 3-7. In some examples, the transistor 102 has at least 3 total terminals, at least 4 total terminals, at least 5 total terminals, at least 6 total terminals, or at least 7 total terminals. In some examples, the transistor 102 has at most 7 total terminals, at most 6 total terminals, at most 5 total terminals, at most 4 total terminals, or 3 total terminals.

### System for Determining Turn-On Voltage for a Transistor That Entered an On-State

The system 100 may include at least one voltage system 112 and at least one current system 114, which are configured to test the transistor 102 by applying a range of voltages to the transistor 102 (e.g., using the at least one voltage system 112) and measuring currents from the transistor 102 (e.g., using the at least one current system 114). The at least one voltage system 112 may be any system configured to apply the range of voltages to the transistor 102. For instance, the at least one voltage system 112 may be a battery, generator, power supply, arbitrary waveform generator, or digital acquisition card (DAC). The at least one voltage system 112 may be electrically connected (e.g., via cables, adaptors, etc.) to at least one terminal of the transistor 102. For instance, the at least one voltage system 112 may be electrically connected to the second terminal 106 (e.g., gate terminal) of the transistor 102

The at least one current system 114 may be any system configured to measure currents from the transistor 102, in which the currents result from the range of voltages applied by the at least one voltage system 112. For instance, the at least one current system 114 may be a multimeter, ammeter, current clamp, current probe, analog-to-digital convertor, digitizer, or DAC. The at least one current system 114 may similarly be electrically connected (e.g., via cables, adaptors, etc.) to at least one terminal of the transistor 102. For instance, the at least one current system 114 may be electrically connected to the third terminal 108 (e.g., drain terminal) of the transistor 102.

The system 100 may include a control system 116, and the control system 116 may be configured to control the at least one voltage system 112 to apply the range of voltages to the transistor 102. For instance, the control system 116 may be connected to the at least one voltage system 112 (e.g., via electrical connections or wirelessly), and the control system 116 may command, instruct, trigger, etc. the at least one voltage system 112 to apply each voltage in the range of voltages to the transistor 102. The control system 116 may command, instruct, trigger, etc. the at least one voltage system 112 to apply each voltage in the range of voltages at a magnitude and/or a duration. In some embodiments, the control system 116 may transmit commands, instructions, triggers, etc. to the at least one voltage system 112. In response to the commands, instructions, triggers, etc., the at least one voltage system 112 may apply each voltage in the range of voltages to the transistor 102. In some embodiments, the commands, instructions, trigger, etc. from the control system 116 include a magnitude and/or duration of each voltage in the range of voltages.

The magnitude of each voltage in the range of voltages may be in a range of −10 V to 10 V, for instance at least −10 V, at least −9 V, at least −8 V, at least −7 V, at least −6 V, at least −5 V, at least −4 V, at least −3 V, at least −2 V, at least −1 V, or at least 0 V. In some embodiments, the at least one voltage system 112 may apply each voltage of the range of voltages to the transistor 102 with a magnitude of at most 10 V, at most 9 V, at most 8 V, at most 7 V, at most 6 V, at most 5 V, at most 4 V, at most 3 V, at most 2 V, or at most 1 V. In some embodiments, the magnitude of each voltage in the range of voltages is in a range of 0.0 V to 5.0 V, for instance, 0.0 V, at least 0.1 V, at least 0.2 V, at least 0.3 V, at least 0.4 V, at least 0.5 V, at least 0.6 V, at least 0.7 V, at least 0.8 V, at least 0.9 V, at least 1.0 V, at least 1.1 V, at least 1.2 V, at least 1.3 V, at least 1.4 V, at least 1.5 V, at least 1.6 V, at least 1.7 V, at least 1.8 V, at least 1.9 V, at least 2.0 V, at least 2.5 V, at least 3.0 V, at least 3.5 V, at least 4.0 V, at least 4.5 V, or at least 5.0 V. In some embodiments, the magnitude of each voltage in the range of voltages is at most 5.0 V, at most 4.5 V, at most 4.0 V, at most 3.5 V, at most 3.0 V, at most 2.5 V, at most 2.0 V, at most 1.9 V, at most 1.8 V, at most 1.7 V, at most 1.6 V, at most 1.5 V, at most 1.4 V, at most 1.3 V, at most 1.2 V, at most 1.1 V, at most 1.0 V, at most 0.9 V, at most 0.8 V, at most 0.7 V, at most 0.6 V, at most 0.5 V, at most 0.4 V, at most 0.3 V, at most 0.2 V, or at most 0.1 V.

In some embodiments, the control system 116 commands, instructs, triggers, etc. the at least one voltage system 112 to temporally apply each voltage in the range of voltages to the transistor 102 in accordance with the magnitude of each voltage in the range of voltages. For instance, the control system 116 may command, instruct, trigger, etc. the at least one voltage system 112 to first apply the smallest magnitude voltage in the range of voltages to the transistor 102 and then apply each subsequentially higher magnitude voltage in the range of voltages to the transistor 102. As such, the first voltage applied to the transistor 102 is the smallest magnitude voltage in the range of voltages, and the last voltage applied to the transistor 102 is the largest magnitude voltage in the range of voltages.

The control system 116 may be connected (e.g., via electrical connections or wirelessly) to the at least one current system 114. As such, the control system 116 may also be configured to receive currents measured by the at least one current system 114. For instance, the control system 116 may receive a current, or a plurality of currents, measured by the at least one current system 114 from the transistor 102 in response to each applied voltage in the range of applied voltages (e.g., each voltage in the range of voltages applied to the transistor 102 by the at least one voltage system 112). In some embodiments, the control system 116 is configured to control the at least one current system 114 to measure currents. For instance, the control system 116 may command, instruct, trigger, etc. the at least one current system 114 to measure the current, or the plurality of currents, resulting from each applied voltage in the range of applied voltages, for a duration.

In some embodiments, a magnitude of each current received by the control system 116 is in a range of 1 pA to 50 nA, for instance, at least 1 pA, at least 2 pA, at least 3 pA, at least 4 pA, at least 5 pA, at least 6 pA, at least 7 pA, at least 8 pA, at least 9 pA, at least 10 pA, at least 20 pA, at least 30 pA, at least 40 pA, at least 50 pA, at least 60 pA, at least 70 pA, at least 80 pA, at least 90 pA, at least 100 pA, at least 200 pA, at least 300 pA, at least 400 pA, at least 500 pA, at least 600 pA, at least 700 pA, at least 800 pA, at least 900 pA, at least 1 nA, at least 2 nA, at least 4 nA, at least 6 nA, at least 8 nA, at least 10 nA, at least 20 nA, at least 30 nA, at least 40 nA, or at least 50 nA. In some embodiments, a magnitude of each current received by the control system 116 is at most 50 nA, at most 40 nA, at most 30 nA, at most 20 nA, at most 10 nA, at most 8 nA, at most 6 nA, at most 4 nA, at most 2 nA, at most 1 nA, at most 900 pA, at most 800 pA, at most 700 pA, at most 600 pA, at most 500 pA, at most 400 pA, at most 300 pA, at most 200 pA, at most 100 pA, at most 90 pA, at most 80 pA, at most 70 pA, at most 60 pA, at most 50 pA, at most 40 pA, at most 30 pA, at most 20 pA, at most 10 pA, at most 9 pA, at most 8 pA, at most 7 pA, at most 6 pA, at most 5 pA, at most 4 pA, at most 3 pA, at most 2 pA, or at most 1 pA. In some embodiments, the control system 116 normalizes each measured current into in a range of 0 a.u. to 1 a.u. (e.g., arbitrary units).

The control system 116 may display, store, and/or process the range of voltages applied to the transistor 102 and/or the currents measured from the transistor 102. For instance, the control system 116 may store the range of applied voltages in a voltage array, in which the range of applied voltages are ordered in the voltage array in accordance with their magnitudes (e.g., in accordance with the application of each voltage in time, such as described herein). As such, a first indexed value of the voltage array is the smallest magnitude voltage applied to the transistor 102 (e.g., the first voltage applied to the transistor 102) and a last indexed value of the voltage array is the highest magnitude voltage applied to the transistor 102 (e.g., the last voltage applied to the transistor 102). In some embodiments, if a plurality of currents is measured by the at least one current system 114 for each applied voltage in the range of applied voltages, the control system 116 averages the plurality of measured currents and stores a subsequently averaged measured current for each applied voltage in the range of applied voltages. The control system 116 may similarly store the measured currents (or the averaged measured currents) in a current array, in which the measured currents (or the averaged measured currents) are ordered in the current array in accordance with the voltage array. As such, a first indexed value of the current array is the measured current (or the averaged measured current) resulting from the first voltage applied to the transistor 102, and a last indexed value of the current array is the measured current (or the averaged measured current) resulting from the last voltage applied to the transistor 102. In some embodiments, the current array and the voltage array are rows of a matrix. For instance, a first row of the matrix may be the voltage array and a second row of the matrix may be the current array.

In some embodiments, the control system 116 plots the measured currents (or averaged measured currents) versus the range of applied voltages. FIG. 1B is an exemplary plot of simulated measured currents (e.g., currents that may be measured from a simulated transistor, such as transistor 102) versus a range of simulated applied voltages (e.g., applied to a simulated transistor). FIG. 1B illustrates a transition from a low simulated measured current state 130 to a linear-like increase in the magnitude of the simulated measured currents 132, which may indicate that the transistor entered an on-state during testing (e.g., when a range of voltages may be applied to the transistor and currents may be measured from the transistor). Particularly, the low simulated measured current state 130 indicates the transistor is off (e.g., negligible conduction) when the simulated voltages associated with the low simulated measured current state 130 may be applied to a simulated transistor. The linear-like increase in the magnitude of the simulated measured currents 132 indicates the simulated transistor is on when the voltages associated with the linear-like increase 132 may be applied to the simulated transistor. Referring back to FIG. 1A, in some embodiments, the control system 116 plots the measured currents (or the averaged measured currents) versus the voltage array index, such as depicted in FIG. 1C by the simulated measured currents.

In some embodiments, the at least one current system 114 is configured to measure voltages across a load resistance resulting from the range of voltages applied by the at least one voltage system 112. A person of skill in the art will appreciate that the aforementioned is equally applicable if the at least one current system 114 measures voltages across the load resistance. In some embodiments, the control system 116 is configured to receive the measured voltages and convert the measured voltages to currents (e.g., using Ohm's law). A person of skill in the art will further appreciate that the aforementioned is equally applicable if the control system 116 converts the measured voltages to currents. A person of skill in the art will appreciate that the at least one current system 114 may be configured to: 1) amplify the currents resulting from the range of voltages applied by the at least one voltage system 112 and/or convert the currents (or amplified currents) resulting from the range of voltages applied by the at least one voltage system 112 to voltages (or amplified voltages), and 2) measure the voltages (or amplified voltages) or measure the amplified currents. For instance, the at least one current system 114 may include a transimpedance amplifier that converts and amplifies the currents resulting from the range of voltages applied by the at least one voltage system 112. The at least one current system 114 may also be configured to take as an input the measured amplified voltages and output currents associated with the measured amplified voltages (e.g., the at least one current system 114 is configured to convert the measured amplified voltages to currents). The control system 116 may receive, store, process, and/or display the measured amplified voltages, the measured voltages, the measured amplified currents, or the measured amplified voltages converted back to currents.

The system 100 may include an on-state detection machine learning model 118 configured to identify whether the transistor 102 entered the on-state using inputted data, such as the measured currents (or averaged currents). The inputted data may also include the range of applied voltages. In some embodiments, the inputted data may be data obtained from a third-party, such as data published or otherwise made available by industry, academia, and/or government. As such, the on-state detection machine learning model 118 may be configured to identify whether a transistor that is associated with the inputted data from the third-party entered an on-state. In some embodiments, the inputted data may represent data (e.g., such as measured currents or obtained from the third-party) associated with a plurality of transistors (e.g., such as a plurality of transistors 102). As such, the on-state detection machine learning model 118 may be configured to identify whether each transistor of the plurality of transistors enters the on-state using each transistor's associated data in the inputted data. A person of skill in the art will appreciate that the following is equally applicable for data inputted from the third-party and/or data inputted that is associated with the plurality of transistors.

The on-state detection machine learning model 118 may be a convolutional neural network model (e.g., such as a residual network (ResNet)-18 model), a recurrent neural network model, a transformer-based model, or a classifier model (e.g., such as a random forest classifier model, a decision tree model, or a gaussian process classifier). The on-state detection machine learning model 118 may attempt to identify one or more features in the inputted data indicating that the transistor 102 entered the on-state. The one or more features indicating the transistor 102 entered the on-state may be a transition from a low current state to a linear-like increase in the magnitude of the inputted data (e.g., such as depicted in FIG. 1B), transition from a low current state to a quadratic-like increase in the magnitude of the inputted data, or a transition from a low current state to an exponential-like increase in the magnitude of the inputted data.

The on-state detection machine learning model 118 may produce one or more classification outputs indicating whether the transistor 102 entered the on-state (e.g., whether the inputted data indicates the transistor 102 entered the on-state). For instance, the one or more classification outputs from the on-state detection machine learning model 118 may be a binary label, in which a first state of the binary label indicates the inputted data represents that the transistor 102 entered the on-state and a second state of the binary label indicates the inputted data does not represent that the transistor 102 entered the on-state. In some embodiments, the one or more classification outputs from the on-state detection machine learning model 118 may be a likelihood that the inputted data indicates the transistor 102 entered the on-state. For instance, the on-state detection machine learning model 118 may output a probability that the inputted data indicates the transistor 102 entered the on-state or a confidence score that the inputted data indicates the transistor entered the on-state. The inputted data may be considered to indicate the transistor 102 entered the on-state if the probability is greater than or equal to 0.5 or the confidence score is greater than or equal to 0.5.

The on-state detection machine learning model 118 may be a part of the control system 116. For instance, the control system 116 may input the data (e.g., the measured currents obtained from testing the transistor 102) into the on-state detection machine learning model 118. The control system 116 may then command, instruct, trigger, etc. the on-state detection machine learning model 118 to identify whether the inputted data indicates that the transistor 102 entered an on-state. The control system 116 may receive the one or more classification outputs from the on-state detection machine learning model 118 indicating whether the transistor 102 entered the on-state. In some embodiments, inputting the data into the on-state detection machine learning model 118 automatically initiates the on-state detection machine learning model 118 to identify whether the inputted data indicates that the transistor 102 entered the on-state (e.g., the on-state detection machine learning model 118 identifies whether the inputted data indicates that the transistor 102 entered the on-state without a command, instruction, trigger, etc. from the control system 116).

The control system 116 may store, display, and/or process the one or more classification outputs from the on-state detection machine learning model 118. For instance, the control system 116 may use the one or more classification outputs from the on-state detection machine learning model 118 to assess whether the turn-on voltage for the transistor 102 can be determined. If the one or more classification outputs from the on-state detection machine learning model 118 indicate that the transistor 102 did not enter the on-state, then the control system 116 may determine that the turn-on voltage for the transistor 102 cannot be determined. However, if the one or more classification outputs from the on-state detection machine learning model 118 indicate that the transistor 102 entered the on-state, then the control system 116 may determine the turn-on voltage for the transistor 102 can be determined.

The system 100 may include a turn-on region finding machine learning model 120 configured to determine a current turn-on region of the inputted data, such as the data obtained from testing the transistor 102, the data obtained from the third-party, and/or the data associated with the plurality of transistors. The turn-on region finding machine learning model 120 may be a semantic segmentation neural network model, such as a U-Net model or a transformer-based model. The current turn-on region of the inputted data may be a portion of the inputted data from which the turn-on voltage for a transistor can be determined. For instance, the current turn-on region may be the portion of the inputted data that includes the transition from the low current state to the linear-like increase in the magnitude of the inputted data, such as the transition illustrated in FIG. 1B. As such, the turn-on region finding machine learning model 120 may attempt to determine the current turn-on region of the inputted data by identifying one or more features indicative of the current turn-on region, such as the portion of the inputted data with the transition from the low current state to the linear-like increase in the magnitude of the inputted data (e.g., such as depicted in FIG. 1B), the portion of the inputted data with a transition from a low current state to a quadratic-like increase in the magnitude of the inputted data, or the portion of the inputted data with a transition from a low current state to an exponential-like increase in the magnitude of the inputted data. The turn-on region finding machine learning model 120 may be configured to label the current turn-on region of the inputted data with a first identifier (e.g., such as, a first binary digit) and configured to label the inputted data not including the current turn-on region with a second identifier (e.g., such as, a second binary digit). For instance, the turn-on region finding machine learning model 120 may label each value of the inputted data with an identifier based on whether each value of the inputted data is associated with the current turn-on region of the inputted data. In some examples, the turn-on region finding machine learning model 120 labels each value of the inputted data with an identifier based on a probability of whether each value of the inputted data is associated with the current turn-on region of the inputted data. For instance, if a value of the inputted data has a probability greater than or equal to 0.5, then the turn-on region finding machine learning model 120 may label said value of the inputted data with the first identifier. If the value of the inputted data has a probability less than 0.5, then the turn-on region finding machine learning model 120 may label said value of the inputted data with the second identifier. In some examples, the turn-on region finding machine learning model 120 labels each value of the inputted data with the probability of whether each value of the inputted data is associated with the current turn-on region of the inputted data. The probabilities may be outputs from a softmax function of the turn-on region find machine learning model 120.

As such, the turn-on region finding machine learning model 120 may produce an array of the identifiers that is the same length as the inputted data and in which each element of the array is either the first identifier or the second identifier associated with each value of the inputted data. In some examples, the turn-on region finding machine learning model 120 produces an array of the probabilities, in which each element of the array is the probability that a value of the inputted data is associated with the current turn-on region of the inputted data. The control system 116 may then threshold the array of probabilities into an array of identifiers. For instance, the control system 116 may make the array of identifiers such that an element of the array of identifiers is labeled with the first identifier by the control system 116 if the associated element of the array of probabilities is greater than or equal to 0.5 and an element of the array of identifiers is labeled with the second identifier by the control system 116 if the associated element of the array of probabilities is less than 0.5. As such, the array of probabilities produced by the turn-on region finding machine learning model 120 may be interpreted as an array of identifiers, in which a probability greater than or equal to 0.5 is interpreted as the first identifier and a probability less than 0.5 is interpreted as the second identifier.

In some embodiments, the current turn-on region of the inputted data includes any integer number of values of the inputted data in a range of 2-7, such as at least 2 values of the inputted data, at least 3 values of the inputted data, at least 4 values of the inputted data, at least 5 values of the inputted data, at least 6 values of the inputted data, or at least 7 values of the inputted data. In some embodiments, the current turn-on region includes at most 2 values of the inputted data, at most 3 values of the inputted data, at most 4 values of the inputted data, at most 5 values of the inputted data, at most 6 values of the inputted data, or at most 7 values of the inputted data. As such, the turn-on region machine may be configured to determine a current turn-on region that includes a pre-defined integer number of values of the inputted data. For instance, the turn-on region finding machine learning model 120 may be trained to determine the current turn-on region of the inputted data that includes 5 values of the inputted data. In some embodiments, if the turn-on region finding machine learning model 120 is configured to determine the current turn-on region that includes a pre-defined integer number of values of the inputted data and the turn-on region finding machine learning model 120 cannot determine such a current turn-on region, the turn-on region finding machine learning model may attempt to determine a current turn-on region by decreasing the pre-defined integer number by 1 until a current turn-on region can be determined. For instance, if the turn-on region finding machine learning model 120 is configured to determine the current turn-on region that includes 5 values of the inputted data, but it cannot determine such a current turn-on region, the turn-on region finding machine learning model 120 may attempt to determine the current turn-on region that includes 4 values of the inputted data. If the turn-on region finding machine learning model 120 cannot determine a current turn-on region with 4 values of the inputted data, then the turn-on region finding machine learning model 120 may attempt to determine a current turn-on region that includes 3 values of the inputted data.

The turn-on region finding machine learning model 120 may output the current turn-on region by outputting the array of identifiers. As such, the current turn-on region outputted by the turn-on region finding machine learning model 120 may be a plurality of the first identifiers grouped together in the array of identifiers. The current turn-on region outputted by the turn-on region finding machine learning model 120 may be any integer number of first identifiers grouped together in a range of 2 to 7, such as at least 2 first identifiers grouped together, at least 3 first identifiers grouped together, at least 4 first identifiers grouped together, at least 5 first identifiers grouped together, at least 6 first identifiers grouped together, or at least 7 first identifiers grouped together in the array of identifiers. In some embodiments, the current turn-on region outputted by the turn-on region finding machine learning model 120 is at most 2 first identifiers grouped together, at most 3 first identifiers grouped together, at most 4 first identifiers grouped together, at most 5 first identifiers grouped together, at most 6 first identifiers grouped together, or at most 7 first identifiers grouped together in the array of identifiers. FIG. 1C is an exemplary plot of simulated measured currents of a transistor inputted into a turn-on region finding machine learning model and an array of identifiers outputted from the turn-on region finding machine learning model. FIG. 1C illustrates that the turn-on region finding machine learning model outputs the current turn-on region by outputting the array of identifiers. For instance, the current turn-on region of the transistor of FIG. 1C is labeled via a first identifier (e.g., 1), while the other simulated measured currents not in the current turn-on region are labeled via a second identifier (e.g., 0).

Referring back to FIG. 1A, in some embodiments, the array of identifiers outputted by the turn-on region finding machine learning model 120 may include pluralities of first identifiers grouped together in the array of identifiers. For instance, the turn-on region finding machine learning model 120 may have determined multiple portions of the inputted data in which the turn-on voltage of the transistor 102 may be determined (e.g., determined multiple current turn-on regions). The pluralities of first identifiers grouped together in the array of identifiers may have the same integer number of first identifiers or may not have the same integer number of first identifiers. For instance, a first plurality of first identifiers grouped together in the array of identifiers may have 3 identifiers grouped together and a second plurality of first identifiers grouped together in the array of identifiers may have 5 identifiers grouped together.

The turn-on region finding machine learning model 120 may be a part of the control system 116. For instance, the control system 116 may input the data into the turn-on region finding machine learning model 120 and then command, instruct, trigger, etc. the turn-on region finding machine learning model 120 to determine the current turn-on region of the inputted data. The control system 116 may then receive the current turn-on region from the turn-on region finding machine learning model 120 (e.g., by receiving the array of identifiers). In some embodiments, inputting the data into the turn-on region finding machine learning model 120 automatically initiates the turn-on region finding machine learning model 120 to determine the current turn-on region of the inputted data (e.g., the turn-on region finding machine learning model 120 determines the current turn-on region of the inputted data without a command, instruction, trigger, etc. from the control system 116). In some embodiments, the control system 116 stores, displays, processes, and/or uses the current turn-on region from the turn-on region finding machine learning model 120.

The control system 116 may also be configured to identify the turn-on voltage for the transistor 102 within the current turn-on region outputted by the turn-on region finding machine learning model 120. The control system 116 may first correlate the current turn-on region to the previously stored voltage array. For instance, the control system 116 may correlate the indices associated with the current turn-on region of the array of identifiers to the associated indices of the voltage array. As such, the control system 116 may use the current turn-on region to select from the voltage array which applied voltages are in accordance with the current turn-on region. The control system 116 may then determine the turn-on voltage for the transistor 102 by calculating an average voltage of the applied voltages associated with the current turn-on region. In some embodiments, the control system 116 determines the turn-on voltage for the transistor 102 by calculating a midpoint voltage of the applied voltages associated with the current turn-on region.

If the array of identifiers outputted by the turn-on region finding machine learning model 120 includes the pluralities of first identifiers (e.g., multiple current turn-on regions), the control system 116 may select the current turn-on region for determining the turn-on voltage based on the total number of first identifiers grouped together in each plurality of first identifiers and/or the location of each plurality of first identifiers in the array of identifiers. For instance, if a first plurality of first identifiers includes 3 first identifiers grouped together and a second plurality of first identifiers includes 5 first identifiers grouped together, the control system 116 may select the second plurality of first identifiers for determining the turn-on voltage. The control system 116 may select the second plurality of first identifiers as the second plurality of first identifiers includes a greater number of first identifiers grouped together, which may indicate that the inputted data associated with these first identifiers illustrates clearer, more obvious, and/or more features indicative of a current turn-on region in which the turn-on voltage can be determined. In some embodiments, a first plurality of first identifiers includes 5 first identifiers grouped together and a second plurality of first identifiers also includes 5 first identifiers grouped together, but when the second plurality of first identifiers is correlated to the voltage array it includes voltages of magnitude greater than the voltages correlated to the first plurality of first identifiers. As such, the control system 116 may select the second plurality of first identifiers for determining the turn-on region as the current turn-on region associated with higher voltages may be more likely to be a current turn-on region in which the turn-on voltage can be determined. If the array of identifiers includes the pluralities of first identifiers (e.g., multiple current turn-on regions), the control system 116 may select the current turn-on region for determining the turn-on voltage based on an average probability associated with each plurality of first identifiers. Such as described herein, the turn-on region machine learning model 120 may produce the array of probabilities, in which each element of the array is the probability that a value of the inputted data is associated with the current turn-on region of the inputted data. The array of probabilities may be interpreted as an array of identifiers, and the control system 116 may threshold the array of probabilities into an array of identifiers. The array of identifiers may have a first plurality of first identifiers that includes 3 first identifiers grouped together and a second plurality of first identifiers that includes 5 first identifiers grouped together. The average probability of the probabilities associated with the first plurality of first identifiers may be compared to the average probability of the probabilities associated with the second plurality of first identifiers. For instance, if the average probability of the probabilities associated with the first plurality of first identifiers is larger than the average probability of the probabilities associated with the second plurality of first identifiers, then the control system 116 may select the first plurality of first identifiers as the current turn-on region.

The control system 116 may use the determined turn-on voltage for the transistor 102 to operate the transistor 102. For instance, the control system 116 may turn off the transistor 102 by controlling the at least one voltage system 112 to apply a voltage to the transistor 102 that is less than the turn-on voltage. Alternatively, the control system 116 may turn on the transistor 102 by controlling the at least one voltage system 112 to apply a voltage to the transistor 102 that is greater than or equal to the turn-on voltage.

In some embodiments, the system 100 includes the transistor 102. In some embodiments, the system 100 does not include the transistor 102, such that the transistor 102 is provided by a user of the system 100. In some embodiments, the system 100 determines the turn-on voltage for a transistor not tested by the system 100. For instance, the system 100 may determine the turn-on voltage for data associated with a transistor that was obtained without testing the transistor. The data associated with the transistor that was obtained without testing the transistor may be data previously obtained from testing the transistor and stored by the control system 116 or data obtained from the third-party (e.g., such as described herein). In some embodiments, the system 100 is configured to determine a turn-on voltage for a plurality of transistors (e.g., such as a plurality of transistors 102) by testing each transistor of the plurality of transistors, identifying whether each transistor entered an on-state, and if one or more transistors entered the on-state, determining the turn-on voltage for each transistor of the one or more transistors that entered the on-state.

Two machine learning models can be used (e.g., the on-state detection machine learning model 118 and the turn-on region finding machine learning model 120) to determine the turn-on voltage for a transistor as using two machine learning models diminishes uncertainty associated with determining the turn-on voltage for the transistor. If a machine learning model is configured to both identify whether a transistor entered an on-state and determine a turn-on voltage for a transistor that entered the on-state, it may be unclear how to attribute failure in operating the transistor. For instance, if the determined turn-on voltage failed to turn on the transistor, it becomes unclear whether to attribute the failure to the machine learning model inaccurately identifying that the transistor entered the on-state or inaccurately determining the turn-on voltage. However, with two machine learning models, failure in operating the transistor can more easily be attributed to either an inaccurate identification that the transistor entered the on-state or an inaccurate identification of the turn-on voltage. For instance, if the determined turn-on voltage failed to turn on the transistor, a user can examine the output from the on-state detection machine learning model 118 to determine if the on-state detection machine learning model 118 failed to identify that the transistor did not enter the on-state and examine the output from the turn-on region finding machine learning model 120 to determine if the turn-on region finding machine learning model 120 failed to determine a current turn-on region of the transistor.

The systems and methods described herein for determining a turn-on voltage for a transistor may be technically more advantageous than conventional systems and methods. For instance, conventional systems and methods estimate the turn-on voltage by manually thresholding current-voltage data into the off-state and the on-state using a pre-defined current threshold or pre-defined slope change threshold, such that the voltage associated with the pre-defined current threshold or pre-defined slope change threshold is the turn-on voltage. As such, the conventional systems and methods often struggle with transistor-to-transistor variability, measurement noise, or temperature fluctuations, which diminishes the accuracy of the estimated turn-on voltage, and thus diminishes the reliability of the transistor for use in electronic devices. The systems and methods described herein may determine the turn-on voltage for the transistor using the two machine learning models (e.g., the on-state detection machine learning model 118 and the turn-on region finding machine learning model 120) that are configured to handle a variety of data including data with excessive noise, reduced signal-to-noise ratio, incomplete information etc. As such, the systems and methods described herein may be more robust to transistor-to-transistor variability, measurement noise, and/or temperature fluctuations, and thus the systems and methods described herein may more accurately and precisely determine the turn-on voltage for the transistor. The on-state detection machine learning model 118 and the turn-on region finding machine learning model 120 of the system 100 may be configured to handle a variety of data because they are trained using a broad data distribution (e.g., broad range of current values, large variety of data illustrating or not illustrating transistors entering the on-state), a broad transistor parameter distribution, and/or data with various noise profiles.

### Training an On-State Detection Machine Learning Model

The first machine learning model of the two machine learning models of the systems and methods described herein is an on-state detection machine learning model that is configured to identify whether applying a range of voltages to a transistor eventually causes the transistor to turn on (e.g., does the transistor enter an on-state). The on-state detection machine learning model may take as an input transistor data, such as the range of voltages applied to the transistor and/or currents, resulting from the range of applies voltages, measured from the transistor. The on-state detection machine learning model may attempt to identify one or more features of the inputted data indicative of a transistor entering an on-state. The one or more features may be a transition from a low current state to a linear-like increase in the magnitude of the inputted data, a transition from a low-current state to a quadratic-like increase in the magnitude of the inputted data, or a transition from a low-current state to an exponential-like increase in the magnitude of the inputted data. The on-state detection machine learning model may output a classification indicating whether the inputted data represents a transistor that entered an on-state.

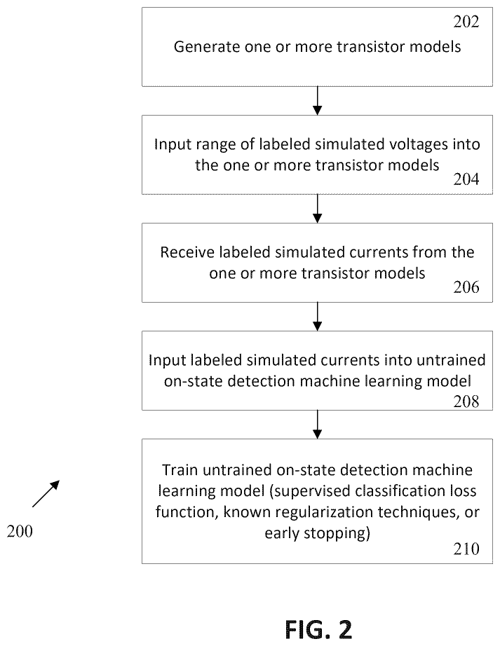

FIG. 2 illustrates a method 200 of training an un-trained on-state detection machine learning model with labeled simulated data generated by one or more transistor models modeling behavior of transistor(s). In step 202, the one or more transistor models may be generated. The one or more transistor models may be generated by a control system, such as control system 116 of FIG. 1. For instance, the one or more transistor models may be generated by the control system using one or more equations and/or one or more algorithms configured to model transistor behavior. The transistor behavior modeled by the one or more transistor models may be associated with, or be a consequence of, a plurality of parameters of the transistor(s) (e.g., a broad transistor parameter distribution). For instance, the transistor behavior may be associated with threshold voltage of the transistor (e.g., minimum voltage applied to a FET or MOSFET transistor to begin conduction), channel lengths (e.g., channel lengths of features in the semiconductor material(s) of the transistor), doping concentration of the semiconductor material(s) of the transistor, and/or temperature (e.g., temperature of the transistor itself or a temperature of the environment). The one or more transistor models may be stored, displayed, and/or used by the control system. The one or more transistor models may use a range of simulated voltages as an input, in which a simulated voltage is a voltage that could be applied to a transistor, such as a range of applied voltages described in reference to FIG. 1A. The one or more transistor models may output simulated currents, in which a simulated current is a current that could be measured from a transistor, such as measured currents described in reference to FIG. 1A.

In step 204, a range of labeled simulated voltages may be inputted into the one or more transistor models. The range of simulated voltages may be labeled as it may be known a priori that inputting said range of simulated voltages into the one or more transistor models will yield simulated currents that either represents a transistor entering an on-state or does not represent a transistor entering an on-state. The control system may input the range of labeled simulated voltages into the one or more transistor models. The control system may then command, instruct, trigger, etc., the one or more transistor models to simulate transistor behavior of one or more simulated transistors using the inputted range of labeled simulated voltages. In some embodiments, the control system records, stores, and/or displays the range of labeled simulated voltages. In some embodiments, inputting the range of labeled simulated voltages into the one or more transistor models triggers the one or more transistor models to simulate the behavior of the one or more transistors. The range of labeled simulated voltages may include a broad range of voltage values (e.g., a broad data distribution). In some embodiments, the range of labeled simulated voltages is injected with, overlaid with, or otherwise subjected to one or more noise profiles, such as a Gaussian noise profile, a 1/f noise profile, and/or a baseline shift noise profile.

In step 206, labeled simulated currents may be received from the one or more transistor models. The simulated currents may be labeled as it may be known a priori that inputting the range of simulated voltages in step 204 yields said simulated currents that either represents a transistor entering an on-state or does not represent a transistor entering an on-state. In response to the control system inputting the range of labeled simulated voltages into the one or more transistor models and commanding, instructing, triggering, etc. the one or more transistor models to simulate transistor behavior of one or more simulated transistors using the range of labeled simulated voltages, the one or more transistor models may then output the labeled simulated currents. The control system may record, store, display, and/or use the labeled simulated currents.

The labeled simulated currents may include a broad range of current values. In some embodiments, the labeled simulated currents may be injected with, overlaid with, or otherwise subjected to one or more noise profiles, such as a Gaussian noise profile, a 1/f noise profile, and/or a baseline shift noise profile. In some embodiments, step 204 and step 206 are repeated, such that after N repetitions, the control system recorded N pluralities of labeled simulated currents in response to N ranges of labeled simulated voltages (e.g., each plurality of labeled simulated currents is associated with a range of labeled simulated voltages).

In some embodiments, the labeled simulated currents are received from a third-party. For instance, the control system may receive labeled simulated currents that are published or otherwise made available by industry, academia, and/or government. In some embodiments, the control system also receives a range of labeled simulated voltages that are also published or otherwise made available by industry, academia, and/or government. In some embodiments, the control system receives labeled measured currents. For instance, the control system may receive labeled measured currents (and a range of labeled applied voltages) obtained using a system that is an exemplary embodiment of system 100 of FIG. 1A. In some embodiments, the control system receives a range of labeled voltages applied to a transistor, such as described in system 100 of FIG. 1A. In some embodiments, the control system receives labeled measured currents (or labeled measured currents and a range of labeled applied voltages) from the third-party.

In some embodiments, the measured currents (or the measured currents and the range of applied voltages) is not labeled, such that it may be relevant to label the measured currents for use in the training of the untrained on-state detection machine learning model (e.g., step 210). The labeling may indicate whether the measured currents represent a transistor entering the on-state or a transistor not entering the on-state. In some embodiments, the measured currents are labeled by a user. For instance, the user may visually examine the measured currents to identify one or more features indicative of a transistor entering the on-state, such as a transition from a low current state to a linear-like increase in the magnitude of the measured currents. If the one or more features are present, the measured currents are labeled as indicative of a transistor entering the on-state. If the one or more features are not present, the measured currents are labeled as indicative of a transistor not entering the on-state. In some embodiments, the measured currents are labeled by the control system. For instance, the control system may attempt to identify one or more dramatic, obvious, or otherwise easily programmable features indicative of a transistor entering an on-state. If the one or more features are present, the control system labels the measured currents as indicative of a transistor entering an on-state. If the one or more features are not present, the control system labels the measured currents as indicative of a transistor not entering an on-state.

In step 208, the labeled simulated currents may be inputted into an untrained on-state detection machine learning model. The untrained on-state detection machine learning model may be an untrained convolutional neural network model, an untrained recurrent neural network model, or an untrained transformer-based model. The untrained convolutional neural network model may be an untrained ResNet-18 model. In some embodiments, the untrained on-state detection machine learning model is on the control system. For instance, the control system may assign, input, or otherwise associate the labeled simulated currents as an input of the untrained on-state detection machine learning model. In some embodiments, the control system may normalize the labeled simulated currents and then assign, input, or otherwise associate the normalized labeled simulated currents as an input of the untrained on-state detection machine learning model. In some embodiments, the range of labeled simulated voltages are also inputted into the untrained on-state detection machine learning model. For instance, the control system may assign, input, or otherwise associate the labeled simulated currents and the range of labeled simulated voltages as an input of the untrained on-state detection machine learning model. In some embodiments, the control system assigns, inputs, or otherwise associates the labeled simulated currents (or the labeled simulated currents and the range of labeled simulated voltages) received by the control system from the third-party. In some embodiments, the control system assigns, inputs, or otherwise associates the labeled measured currents (or the labeled measured currents and the range of labeled applied voltages) received by the control system from a system that is an exemplary embodiment of system 100 of FIG. 1A or from the third-party.

In step 210, the untrained on-state detection machine learning model may be trained. For instance, the control system may command, instruct, trigger, etc. the training of the untrained on-state detection machine learning model using the inputted labeled simulated currents (or the inputted labeled simulated currents and the inputted range of labeled simulated voltages).

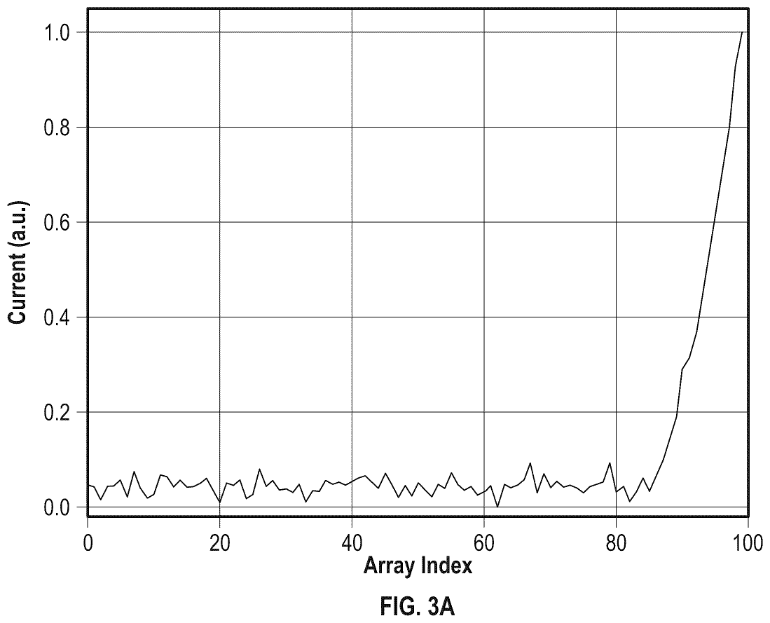

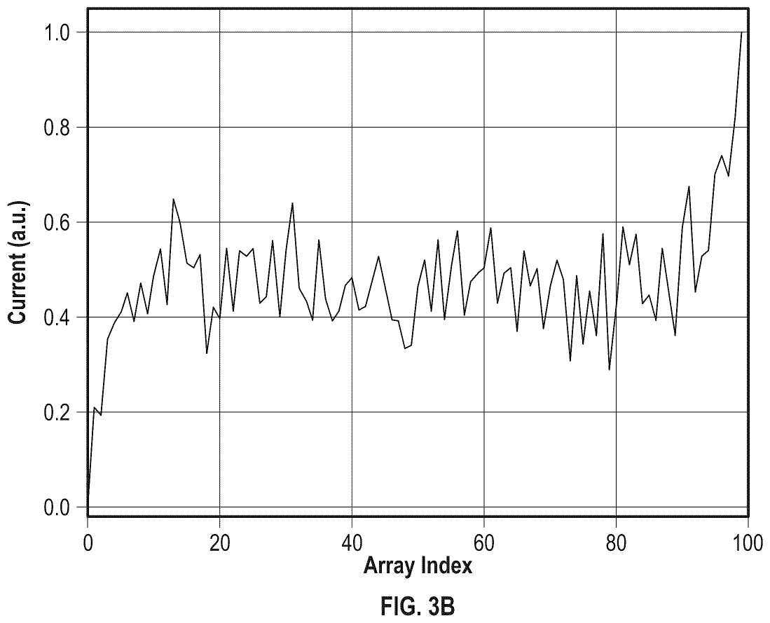

The untrained on-state detection machine learning model may be trained using a supervised classification loss function (e.g., cross entropy, dice loss, Jaccard loss, focal loss, or weighted cross-entropy loss). For instance, the training with the supervised classification loss function may train the on-state detection machine learning model to distinguish between labeled simulated currents that represent transistors entering an on-state and transistors not entering an on-state. FIGS. 3A and 3B are exemplary plots of simulated currents that may be used to train an on-state detection machine learning. FIG. 3A illustrates simulated currents representing a transistor that enters an on-state (e.g., transition from a low current state to a linear-like increase in the magnitude of the labeled simulated data). FIG. 3B illustrates simulated currents representing a transistor that does not enter an on-state. The simulated currents of FIGS. 3A and 3B may be generated by one or more transistor models, such as the one or more transistor models described in reference to step 202 of FIG. 2. In some embodiments, the simulated currents of FIG. 3B are generated via a polynomial function. As such, the labeled simulated currents representing a transistor that does not enter an on-state may not be generated by the one or more transistor models.

Referring back to FIG. 2, the untrained on-state detection machine learning model may be trained with a variety of techniques that generalize the on-state detection machine learning model. For instance, said techniques may encourage the untrained on-state detection machine learning model to learn patterns of the labeled simulated currents provided during training, rather than minutia associated with the labeled simulated currents (e.g., such as noise, outliers, etc.). The training of the untrained on-state detection machine learning model may include using known regularization techniques which add a penalty term to the loss function to increase the generalizability of the on-state detection machine learning model. The regularization used in the training of the untrained on-state detection machine learning model may be Lasso regularization (e.g., L1 regularization), Ridge regularization (e.g., L2 regularization), or Elastic Net regularization (e.g., L1 and L2 regularization). In some embodiments, the regularization may be implemented with labeled simulated currents not previously used to train the untrained on-state detection machine learning model (e.g., validation data). For instance, the training of the untrained on-state detection machine learning model may include training data and validation data. Both the training data and the validation data include labeled simulated currents received in step 206, however the labeled simulated currents of the training data are different than the labeled simulated currents of the validation data. The training data set may be used to initially train the untrained on-state detection machine learning model. The validation data set may be used to fine-tune, or otherwise adjust one or more parameters (e.g., such as adjusting the penalty term of the loss function) of the initially trained on-state detection machine learning model.

In some embodiments, the training of the untrained on-state detection machine learning model includes early stopping, in which the training of the untrained on-state detection machine learning model stops when a validation accuracy plateaus or increases. As the training data is used to train the untrained on-state detection machine learning model, the training may be validated using the validation data. The validation accuracy obtained from validating the training with the validation data may be determined. Similarly, a training accuracy may be determined from the training with the training data. As the training continues, the training accuracy will increase, however eventually the validation accuracy will plateau or decrease due to overfitting of the untrained on-state detection machine learning model to the training data (e.g., on-state detection machine learning model learns minutia, such as described herein). In early stopping, parameters of the untrained on-state detection machine learning model associated with the highest validation accuracy are used as the parameters of the on-state detection machine learning model. While training of the untrained on-state detection machine learning model may continue for many iterations past the highest validation accuracy, the training returns the parameters associated with the highest validation accuracy, and said parameters are used as the parameters of the on-state detection machine learning model.

The output of the method 200 is the on-state detection machine learning model, such as on-state detection machine learning model 118 of FIG. 1A. The on-state detection machine learning model may be used by the systems and methods disclosed herein to identify whether inputted data indicates a transistor entered an on-state.

### Training a Turn-On Region Finding Machine Learning Model

The second machine learning model of the two machine learning models of the systems and method described herein is a turn-on region finding machine learning model that is configured to determine a current turn-on region of transistor data inputted into the turn-region machine learning model. The transistor data may be currents measured from a transistor in response to a range of voltages applied to the transistor. The current turn-on region of the inputted data may be a portion of the inputted data from which a turn-on voltage for a transistor can be determined. For instance, the current turn-on region may be the portion of the inputted data that includes a transition from a low current state to a linear-like increase in the magnitude of the inputted data, a transition from a low current state to a quadratic-like increase in the magnitude of the inputted data, or a transition from a low current state to an exponential-like increase in the magnitude of the inputted data. The turn-on region finding machine learning model may output the current turn-on region of the transistor data. For instance, the turn-on region finding machine learning model may output the current turn-on region within an array of identifiers in which each element of the array is either a first identifier or a second identifier and is associated with each value of the inputted data, such as described in reference to FIG. 1A.

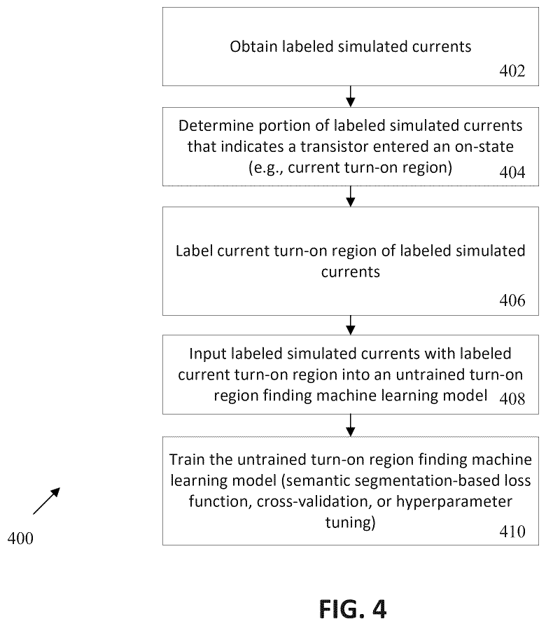

FIG. 4 illustrates a method 400 of training an untrained turn-on region finding machine learning model with labeled simulated currents with a labeled current turn-on region. In step 402, labeled simulated currents may be obtained. For instance, the labeled simulated currents may be obtained from steps 202-206 of method 200 of FIG. 2 and may be stored by a control system (e.g., such as control system 116 of FIG. 1). In some embodiments, a range of labeled simulated voltages inputted into one or more transistor models to produce the labeled simulated currents (e.g., steps 202-206 of method 200 of FIG. 2) is also obtained and stored by the control system. In some embodiments, the labeled simulated currents are obtained by the control system from a third party (e.g., published or otherwise made available by industry, academia, and/or government). In some embodiments, the range of labeled simulated voltages are also obtained by the control system from the third party. In some embodiments, labeled measured currents are obtained by the control system from a system that is an exemplary embodiment of system 100 of FIG. 1A and/or from the third-party. In some embodiments, a range of applied voltages are obtained by the control system from the system that is an exemplary embodiment of system 100 of FIG. 1A and/or from the third-party. In some embodiments, the labeled simulated currents (or the labeled simulated currents and the range of labeled simulated voltages) are obtained by the control system from training data and/or validation data using during training of an untrained on-state detection machine learning, such as described in step 210 of method 200 of FIG. 2.

In step 404, a portion of the labeled simulated currents that indicates a transistor entered an on-state (e.g., a current turn-on region) may be determined. For instance, a user may visually examine the labeled simulated currents to select a portion of the labeled simulated currents at which there is a transition from a low current state to a linear-like increase in the magnitude of the labeled simulated currents, a transition from a low current state to a quadratic-like increase in the magnitude of the labeled simulated currents, or a transition from a low current state to an exponential-like increase in the magnitude of the labeled simulated currents. The portion of the labeled simulated currents determined by the user may include any integer number of values of the labeled simulated currents in a range of 2 values of the labeled simulated data—7 values of the labeled simulated currents. For instance, the portion selected by the user may include at least 2 values of the labeled simulated currents, at least 3 values of the labeled simulated currents, at least 4 values of the labeled simulated currents, at least 5 values of the labeled simulated currents, at least 6 values of the labeled simulated currents, or at least 7 values of the labeled simulated currents. In some embodiments, the portion selected by the user may include at most 2 values of the labeled simulated currents, at most 3 values of the labeled simulated currents, at most 4 values of the labeled simulated currents, at most 5 values of the labeled simulated currents, at most 6 values of the labeled simulated currents, or at most 7 values of the labeled simulated currents. In some embodiments, the current turn-on region is determined from the labeled simulated currents and the range of labeled simulated voltages obtained by the control system from steps 202-206 of method 200 of FIG. 2. In some embodiments, the current turn-on region is determined from the labeled simulated currents (or the labeled simulated currents and the range of labeled simulated voltages) obtained by the controls system from the third-party. In some embodiments, the current turn-on region is determined from the labeled measured currents (or the labeled measured currents and the range of labeled applied voltages) obtained from the system that is an exemplary embodiment of system 100 of FIG. 1A and/or from the third-party.

In some embodiments, the portion of the labeled simulated currents may be determined based on a priori knowledge of the turn-on voltage of the labeled simulated currents. For instance, the turn-on voltage of the labeled simulated currents may be calculated based on the transistor parameters of the one or more transistor models that produced the labeled simulated currents in step 202-206 of method 200 of FIG. 2. The transistor parameters of the one or more transistor models may be any transistor parameters described in reference to step 202 of method 200 of FIG. 2. The control system may use the transistor parameters to calculate the turn-on voltage of the labeled simulated currents, and the control system may store, display, and/or use the calculated turn-on voltage. In some embodiments, the transistor parameters of the one or more transistor models are selected by a user, such that the one or more transistor models output labeled simulated currents associated with a pre-determined turn-on voltage.

The control system may use the calculated turn-on voltage to determine the portion of the labeled simulated currents that indicates the transistor turned on. The control system may correlate the calculated turn-on voltage to a value of the labeled simulated currents. For instance, the control system may determine a voltage index of an array of the range of labeled simulated voltages that matches, or closely matches (e.g., to within 5%), the calculated turn-on voltage. The control system may then determine the value of the labeled simulated currents associated with said voltage index by matching the voltage index to a current index of an array of the labeled simulated currents.

The control system may then determine at least one additional value of the labeled simulated currents proximate to said value of the labeled simulated currents that is correlated to the calculated turn-on voltage. For instance, the control system may determine a first additional value with a current index less than 1 of the current index associated with the turn-on voltage, and the control system may determine a second additional value with a current index greater than 1 of the current index associated with the turn-on voltage. The control system may determine any integer number of additional values of the labeled simulated currents proximate to said value of the labeled simulated currents in a range of 1 to 6 additional values of the labeled simulated currents. In some embodiments, the control system may determine at least 1 additional value, at least 2 additional values, at least 3 additional values, at least 4 additional values, at least 5 additional values, or at least 6 additional values. In some embodiments, the control system may determine at most 6 additional values, at most 5 additional values, at most 4 additional values, at most 3 additional values, at most 2 additional values, or 1 additional value. The portion of the labeled simulated currents may then be the value of the labeled simulated currents correlated to the calculated turn-on voltage and the at least one additional value of the labeled simulated currents.

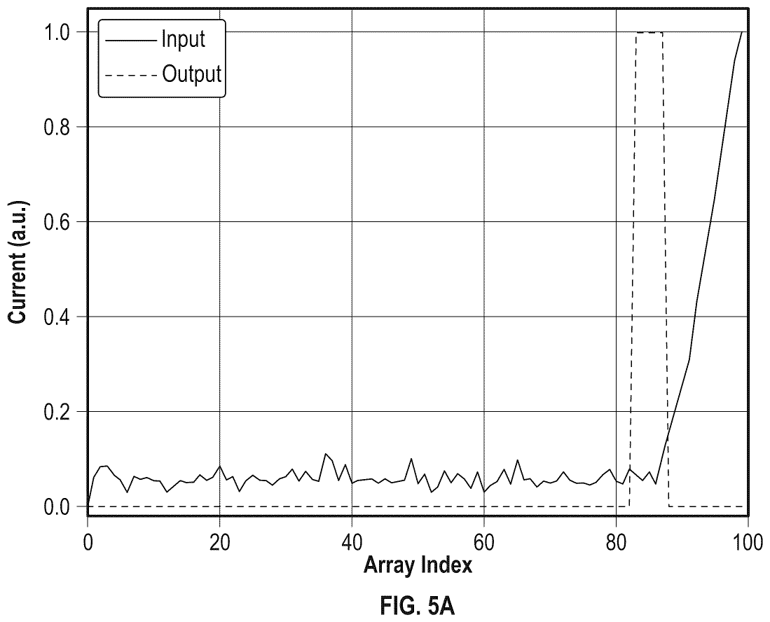

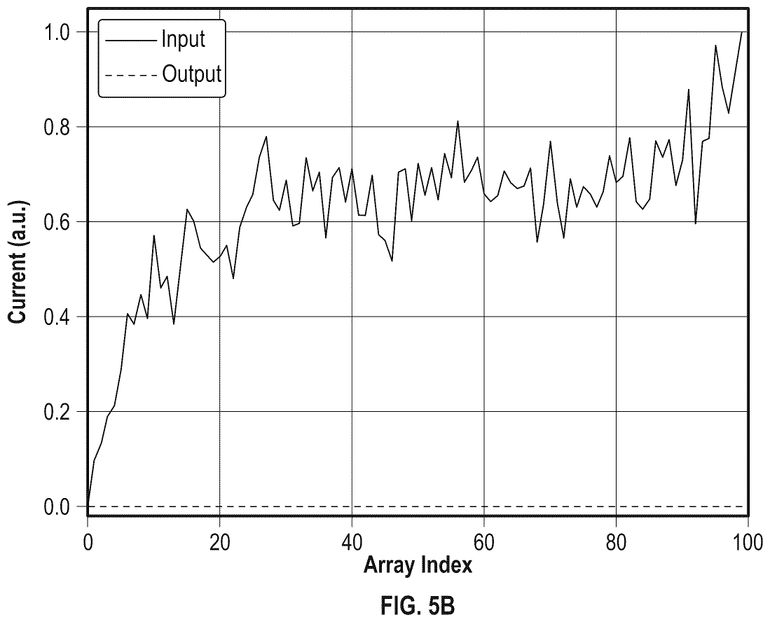

In step 406, the current turn-on region of the labeled simulated currents may be labeled. For instance, once the portion of the labeled simulated currents is determined by the user in step 404, the control system may label the determined portion (e.g., the current turn-on region of the labeled simulated currents) using identifiers. For instance, the control system may label each value of the labeled simulated currents using identifiers. A value of the labeled simulated currents is labeled with a first identifier if the value is included in the current turn-on region and labeled with a second identifier if the value is not included in the current turn-on region. The control system may store the identifiers in an array of identifiers of the same length as the labeled simulated currents, and in which each element of the array of identifiers is either the first identifier or the second identifier. FIG. 5A is an exemplary plot of simulated currents associated with a transistor that entered an on-state overlaid with identifiers marking a current turn-on region of the simulated currents. The current turn-on region of the simulated currents is labeled with a first identifier (e.g., 1), and the remaining values of the labeled simulated currents are labeled with a second identifier (e.g., 0). FIG. 5B is an exemplary plot of simulated currents associated with a transistor that did not enter an on-state overlaid with identifiers not marking a current turn-on region of the simulated currents. Since the simulated currents are associated with a transistor that did not enter an on-state, a current turn-on region is not labeled such that all values of the simulated currents are labeled with a second identifier (e.g., 0). Referring back to FIG. 4, in some embodiments, the current turn-on region of the labeled simulated currents and the range of labeled simulated voltages is labeled. In some embodiments, the current turn-on region of the measured currents (or the measured currents and the range of applied voltages) is labeled.

In some embodiments, the control system labels each value of the labeled simulated currents using the current indexes determined in step 404 based on the calculated turn-on voltage. For instance, the control system may label the value of the labeled simulated currents correlated to the calculated turn-on voltage with the first identifier. The control system may label the at least one value of the labeled simulated currents determined to be proximate to said value of the labeled simulated currents also with the first identifier. The control system may label all other values of the labeled simulated currents with the second identifier.

In step 408, the labeled simulated currents with the labeled current turn-on region (e.g., the array of identifiers) may be inputted into an untrained turn-on region finding machine learning model. The untrained turn-on region finding machine learning model may be an untrained semantic segmentation neural network model, such as a U-Net model or transformer-based model. In some embodiments, the untrained turn-on region finding machine learning model is on the control system (e.g., such as described in reference to FIG. 1A). The control system may assign, input, or otherwise associate the labeled simulated currents with the labeled current turn-on region as an input of the untrained turn-on region finding machine learning model. In some embodiments, the control system may normalize the labeled simulated currents with the labeled current turn-on region and then assign, input, or otherwise associate the normalized labeled simulated currents with the labeled current turn-on region as an input of the untrained turn-on region finding machine learning model. In some embodiments, the control system assigns, inputs, or otherwise associates the labeled simulated currents and the range of labeled simulated voltages with the labeled current turn-on region as an input of the untrained turn-on region finding machine learning model. In some embodiments, the control system assigns, inputs, or otherwise associates the measured currents (or the measured currents and the range of applied voltages) with the labeled current turn-on region as an input of the untrained turn-on region finding machine learning model.

In step 410, the untrained turn-on region finding machine learning model may be trained. For instance, the control system may command, instruct, trigger, etc. the untrained turn-on region finding machine learning model to train using the labeled simulated currents with the labeled current turn-on region inputted in step 408.

The untrained turn-on region finding machine learning model may be trained using a semantic segmentation-based loss function (e.g., cross entropy, binary cross entropy, etc.). In some embodiments, the number of values of the labeled simulated currents included in the labeled current turn-on region configures the turn-on region finding machine learning model to identify current turn-on regions of inputted measured data (e.g., inputted measured currents) with the same number of values. For instance, if the labeled current turn-on region includes 3 values of the labeled simulated currents, then the untrained turn-on region finding machine learning model is trained to identify a current turn-on region that includes 3 values. As such, employing the trained turn-on region finding machine learning model on inputted data, such as described in reference to FIG. 1A, may yield a determined current turn-on region of the inputted data that includes 3 values of the inputted data (e.g., the trained turn-on region finding machine learning model may preferentially attempt to identify a current turn-on region that includes 3 values of the inputted data).

The untrained turn-on region finding machine learning model may additionally be trained with a variety of known techniques to refine the performance of the turn-on region finding machine learning model produced from the training. For instance, the training of the untrained turn-on region finding machine learning model may include cross-validation, such as holdout validation, LOOCV (Leave One Out Cross Validation), stratified cross-validation, or K-fold cross validation. In some embodiments, the training of the untrained turn-on region finding machine learning model includes hyperparameter tuning, in which hyperparameters (e.g., configuration settings of the training of the untrained turn-on region finding machine learning model) are adjusted and then the turn-on region finding machine learning model is retrained with the adjusted hyperparameters. The hyperparameters may be adjusted according to a method for hyperparameter tuning, such as a grid search method, a random search method, or a Bayesian optimization method. In some embodiments, the training of the untrained turn-on region finding machine learning model may include a combination of the cross-validation and hyperparameter tuning. For instance, based on the results of the cross-validation, the hyperparameters may be adjusted and the turn-on machine learning model may be retrained with the adjusted hyperparameters.

The output of the method 400 is the turn-on region finding machine learning model, such as turn-on region finding machine learning model 120 of FIG. 1A. The turn-on region finding machine learning model may be used by the systems and methods described herein to determine a current turn-on region of inputted data.

Method for determining a turn-on voltage for a transistor that entered an on-state

The following is a description of a method for determining a turn-on voltage for a transistor using two machine learning models. A first machine learning model is an on-state detection machine learning model trained, such as using method 200 of FIG. 2, to identify whether the transistor entered an on-state. A second machine learning model is a turn-on region finding machine learning model trained, such as using method 400 of FIG. 2, to determine a current turn-on region of data associated with a transistor that entered an on-state. The method may be performed using a system that is an exemplary embodiment of system 100 of FIG. 1A.

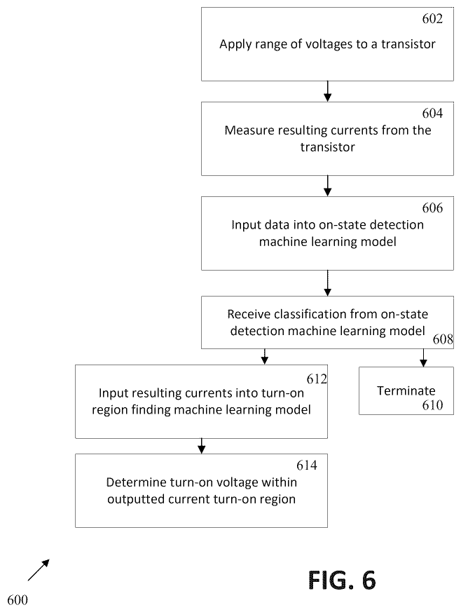

FIG. 6 illustrates an exemplary method 600 for determining a turn-on voltage for a transistor. The transistor may be any transistor described herein, such as transistor 102 of FIG. 1A. In step 602, a range of voltages may be applied to the transistor. The range of voltages may be applied using at least one voltage system, such as at least one voltage system 112 of FIG. 1A. The range of voltages may be applied to at least one terminal of the transistor, such as a first terminal 104, a second terminal 106, or a third terminal 108 of transistor 102 of FIG. 1A. For instance, the at least one voltage system may be electrically connected (e.g., via cables, adaptors, etc.) to the second terminal 106 (e.g., gate terminal) of the transistor 102, such that the at least one voltage system may apply the range of voltages to the transistor via the second terminal 106, such as described in reference to FIG. 1A. In some embodiments, a control system, such as control system 116 of FIG. 1A, controls the at least one voltage system to apply the range of voltages to the transistor. For instance, the control system may command, instruct, trigger, etc. the at least one voltage system to apply each voltage in the range of voltages at a magnitude and for a duration. In some embodiments, the control system commands, instructs, triggers, etc. the at least one voltage system to temporally apply each voltage in the range of voltages to the transistor in accordance with the magnitude of each voltage in the range of voltages, such as described in reference to FIG. 1A. The control system may store, display, and/or process the range of voltages. For instance, the control system may store the range of applied voltages in a voltage array, in which the range of applied voltages are ordered in the voltage array in accordance with their magnitudes (e.g., in accordance with the application of each voltage in time), such as described in reference to FIG. 1A.

In step 604, currents resulting from the range of applied voltages may be measured from the transistor. The resulting currents may be measured using at least one current system, such as at least one current system 114 of FIG. 1A. The resulting currents may be measured from at least one terminal of the transistor, such as a first terminal 104, a second terminal 106, or a third terminal 108 of transistor 102 of FIG. 1A. For instance, the at least one current system may be electrically connected (e.g., via cables, adaptors, etc.) to the third terminal 108 (e.g., drain terminal) of the transistor 102, such that the at least one current system may measure currents from the transistor via the third terminal 108, such as described in reference to FIG. 1A. In some embodiments, the at least one current system measures a current, or a plurality of currents, in response to each voltage in the range of voltages applied to the transistor by the at least one voltage system. The control system may receive, store, display, and/or process the resulting currents measured using the at least one current system. For instance, the control system may similarly store the measured currents in a current array, in which the measured currents are ordered in the current array in accordance with the voltage array, such as described in reference to FIG. 1A. In some embodiments, steps 602 and 604 may be skipped, such that the transistor is not tested by applying the range of voltages and measuring the resulting currents.

In step 606, data may be inputted into an on-state detection machine learning model configured to identify whether the inputted data indicates that a transistor entered an on-state. The data inputted into the on-state detection machine learning model may be the resulting currents measured in step 604. In some embodiments, the data inputted into the on-state detection machine learning model is also the range of voltages applied to the transistor in step 602. In some embodiments, the data inputted into the on-state detection machine learning model is measured currents obtained from a third-party. For instance, the measured currents may be measured currents published or otherwise made available by industry, academia, and/or government. The on-state detection machine learning model may be any on-state detection machine learning model described herein, such as on-state detection machine learning model 118 of FIG. 1A. The on-state detection machine learning model may be trained, such as using method 200 of FIG. 2. The data may be inputted into the on-state detection machine learning model by the control system, and the control system may command, instruct, trigger, etc. the on-state detection machine learning model to identify whether the inputted data indicates a transistor entered an on-state. The on-state detection machine learning model may attempt to identify one or more features of the inputted data indicative of a transistor that entered an on-state. The one or more features indicative of a transistor that entered an on-state may be a transition from a low current state to a linear-like increase in the magnitude of the inputted data (e.g., see FIG. 1B), a transition from a low current state to a quadratic-like increase in the magnitude of the inputted data, or a transition from a low current state to an exponential-like increase in the magnitude of the inputted data. The on-state detection machine learning model may output a classification indicating whether the inputted data represents a transistor that entered the on-state. The classification may be a binary label, such that a first state of the binary label indicates that the inputted data represents a transistor that entered an on-state and a second state of the binary label indicates that the inputted data does not represent a transistor that entered an on-state. In some embodiments, the classification is a likelihood that the inputted data represents a transistor that entered the on-state. For instance, the classification may be a probability or a confidence score.

In step 608, the classification from the on-state machine learning model may be received. For instance, the control system may receive, store, display, and/or use the classification from the on-state machine learning model. If the classification from the on-state machine learning model indicates that the inputted data does not represent a transistor that entered the on-state, then the method 600 is terminated in step 610. If the classification from the on-state machine learning model indicates that the inputted data represents a transistor that entered the on-state, then step 612 may be performed.

In step 612, the data may be inputted into a turn-on region finding machine learning model configured to determine a current turn-on region of the inputted data. The data inputted into the turn-on region finding machine learning model may be the resulting currents measured in step 604. In some embodiments, the data inputted into the turn-on region finding machine learning model is measured currents obtained from a third-party. For instance, the measured currents may be measured currents published or otherwise made available by industry, academia, and/or government. The turn-on region finding machine learning model may be any turn-on region finding machine learning model described herein, such as turn-on region finding machine learning model 120 of FIG. 1A. The turn-on region finding machine learning model may be trained, such as using method 400 of FIG. 4. The data may be inputted into the turn-on region finding machine learning model by the control system, and the control system may command, instruct, trigger, etc. the turn-on region finding machine learning model to determine the current turn-on region of the inputted data. The current turn-on region of the inputted data may be a portion of the inputted data from which the turn-on voltage for a transistor can be determined. For instance, the current turn-on region may be the portion of the inputted data that includes the transition from the low current state to the linear-like increase in the magnitude of the inputted data, such as the transition illustrated in FIG. 1B. As such, the turn-on region finding machine learning model may attempt to determine the current turn-on region of the inputted data by identifying one or more features indicative of the current turn-on region, such as the portion of the inputted data with the transition from the low current state to the linear-like increase in the magnitude of the inputted data (e.g., such as depicted in FIG. 1B), the portion of the inputted data with a transition from a low current state to a quadratic-like increase in the magnitude of the inputted data, or the portion of the inputted data with a transition from a low current state to an exponential-like increase in the magnitude of the inputted data. The turn-on region finding machine learning model may be configured to label the current turn-on region of the inputted data with a first identifier (e.g., such as, a first binary digit) and configured to label the inputted data not including the current turn-on region with a second identifier (e.g., such as, a second binary digit), such as described in reference to FIG. 1A. As such, the turn-on region finding machine learning model may produce an array of identifiers that is the same length as the inputted data and in which each element of the array is either the first identifier or the second identifier associated with each value of the inputted data, such as described in reference to FIG. 1A. The turn-on region finding machine learning model may output the current turn-on region by outputting the array of identifiers, such as described in reference to FIG. 1A. The control system may receive, store, display, and/or process the current turn-on region outputted by the turn-on region finding machine learning model (e.g., the array of identifiers).

In step 614, a turn-on voltage for the transistor may be determined within the current turn-on region outputted by the turn-on region finding machine learning model. For instance, the control system may first correlate the current turn-on region to the previously stored voltage array, such as described in reference to FIG. 1A. As such, the control system may use the current turn-on region to select from the voltage array which applied voltages are in accordance with the current turn-on region. The control system may then determine the turn-on voltage for the transistor by calculating an average voltage of the applied voltages associated with the current turn-on region. In some embodiments, the control system determines the turn-on voltage for the transistor by calculating a midpoint voltage of the applied voltages associated with the current turn-on region. In some embodiments, the control system uses the determined turn-on voltage for the transistor to operate the transistor. For instance, the control system may turn off the transistor by controlling the at least one voltage system to apply a voltage to the transistor that is less than the turn-on voltage. Alternatively, the control system may turn on the transistor by controlling the at least one voltage system to apply a voltage to the transistor that is greater than or equal to the turn-on voltage.

### Transistor Like Devices of a Quantum Device

FIG. 7 is an exemplary embodiment of a system 700 configured to operate each transistor like device of one or more transistor like devices of a quantum device 702. In some embodiments, the quantum device 702 may be composed of any semiconductor material or any combination of semiconductor materials. For instance, the quantum device 702 may be composed of Group-IV semiconductors (e.g., silicon, germanium, tin, etc.), Group-IV compound semiconductors (e.g., silicon germanium, silicon tin, etc.), doped semiconductors (e.g., boron doped silicon, phosphorus doped silicon, etc.), and/or Group-III and Group-V compound semiconductors (e.g., aluminum arsenide, gallium arsenide, indium arsenide, aluminum gallium arsenide, indium gallium arsenide, etc.). The quantum device 702 may include a transistor like device 704, which may be an exemplary embodiment of any transistor like device described herein, such as transistor 102 of FIG. 1A. In some embodiments, the quantum device 702 includes a plurality of transistor like devices, such as a transistor like device 706, 708, 710, and/or 712. The turn-on voltage for each transistor like device of the one or more transistor like devices of the quantum device 702 may be determined using any of the systems and methods described herein, such as system 100 of FIG. 1A or method 600 of FIG. 6.

The system 700 may include a control system 714, which may be any control system described herein, such as control system 116 of FIG. 1A. The control system 714 may receive, store, and/or display the turn-on voltage for each transistor like device determined using any of the systems and methods described herein. The control system 714 may be configured to operate each transistor like device of the one or more transistor like devices of the quantum device 702 using the determined turn-on voltage for each transistor like device. For instance, the control system 714 may be connected (e.g., via electrical connections or wirelessly) to at least one voltage system 716, and the at least one voltage system 716 may be electrically connected (e.g., via cables, adaptors, etc.) to at least one terminal of each transistor like device such as a gate terminal of the transistor like device. The at least one voltage system 716 may be any voltage system described herein, such as at least one voltage system 112 of FIG. 1A. The control system 714 may command, instruct, trigger, etc. the at least one voltage system 716 to apply voltages to each transistor like device based on the determined turn-on voltage for each transistor like device. For instance, the control system 714 may turn off each transistor like device by controlling the at least one voltage system 716 to apply a voltage to each transistor like device that is less than each transistor like device's associated turn-on voltage. Alternatively, the control system 714 may turn on each transistor like device by controlling the at least one voltage system 716 to apply a voltage to each transistor like device that is greater than or equal to each transistor like device's associated turn-on voltage. As such, the system 700 may be used to operate each transistor like device, such that subsequent systems and methods may be used to tune the transistor like device for use in quantum applications, such as quantum computing and quantum sensing. For instance, subsequent systems and methods may apply a voltage greater than or equal to the turn-on voltage to each respective transistor like device to configure each transistor like device for pinch-off (e.g., S-shaped transition in a plot of measured current vs. applied voltage) measurements, Coulomb blockade oscillation (e.g., peaks also in a plot of measured current vs. applied voltage) measurements, or charge stability diagram measurements.

In some examples, the quantum device 700 is configured to operate at a temperature, T. The temperature, T, may be in a range of about 1 mK to 10,000 mK, for instance at least 1 mK, at least 10 mK, at least 20 mK, at least 30 mK, at least 40 mK, at least 50 mK, at least 60 mK, at least 70 mK, at least 80 mK, at least 90 mK, at least 100 mK, at least 200 mK, at least 300 mK, at least 400 mK, at least 500 mK, at least 600 mK, at least 700 mK, at least 800 mK, at least 900 mK, or at least 1,000 mK, at least 2,000 mK, at least 3,000 mK, at least 4,000 mK, at least 5,000 mK, at least 6,000 mK, at least 7,000 mK, at least 8,000 mK, at least 9,000 mK, at least 10,000 mK. In some examples, the temperature, T, is at most 1 mK, at most 10 mK, at most 20 mK, at most 30 mK, at most 40 mK, at most 50 mK, at most 60 mK, at most 70 mK, at most 80 mK, at most 90 mK, at most 100 mK, at most 200 mK, at most 300 mK, at most 400 mK, at most 500 mK, at most 600 mK, at most 700 mK, at most 800 mK, at most 900 mK, or at most 1,000 mK, at most 2,000 mK, at most 3,000 mK, at most 4,000 mK, at most 5,000 mK, at most 6,000 mK, at most 7,000 mK, at most 8,000 mK, at most 9,000 mK, at most 10,000 mK.

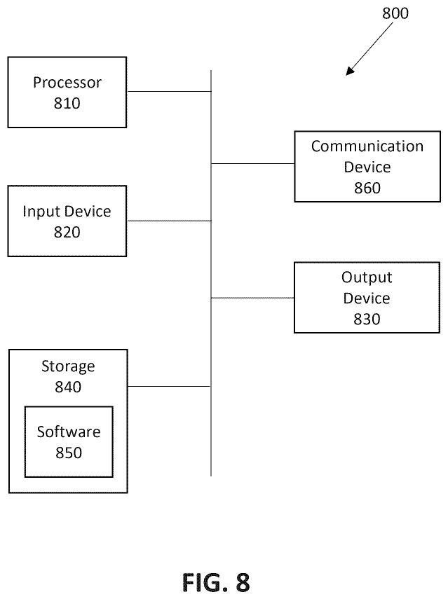

FIG. 8 illustrates an example of a computing system 800 that may be used for any one of the computing systems and devices described herein, such as for control system 116 of FIG. 1A. System 800 can be a computer connected to a network or a NVIDIA DQX QUANTUM system. System 800 can be a client computer, a server, a router, a hub, an access point, or any other computing device that can send and/or receive wireless signals or non-wireless signals. In some examples, system 800 is a component of a microchip that also includes a quantum device, such as quantum device 702 of FIG. 7. As shown in FIG. 8, system 800 can be any suitable type of microprocessor-based system, such as a personal computer, workstation, server, or handheld computing device (portable electronic device) such as a phone or tablet. The system can include, for example, one or more of a processor 810, input device 820, output device 830, storage 840, and communication device 860. Input device 820 and output device 830 can generally correspond to those described above and can either be connectable or integrated with the computer.

Input device 820 can be any suitable device that provides input, such as a touch screen, keyboard or keypad, mouse, gesture recognition component of a virtual/augmented reality system, or voice recognition device. Output device 830 can be or include any suitable device that provides output, such as a touch screen, haptics device, virtual/augmented reality display, or speaker.

Storage 840 can be any suitable device that provides storage, such as an electrical, magnetic, or optical memory, including a RAM, cache, hard drive, removable storage disk, or other non-transitory computer-readable medium. Communication device 860 can include any suitable device capable of transmitting and receiving signals over a network, such as a network interface chip or device. The components of the computer can be connected in any suitable manner, such as via a physical bus or wirelessly.

Software 850, which can be stored in storage 840 and executed by processor 810, can include, for example, the programming that embodies the functionality of the present disclosure (e.g., as embodied in the devices as described above). For example, software 850 can include one or more programs for performing one or more of the steps of method 200 of FIG. 2, method 400 of FIG. 4, or method 600 of FIG. 6.

Software 850 can also be stored and/or transported within any non-transitory computer readable storage medium for use by or in connection with an instruction execution system, apparatus, or device, such as those described above, that can fetch instructions associated with the software from the instruction execution system, apparatus, or device and execute the instructions. In the context of this disclosure, a computer-readable storage medium can be any medium, such as storage 840, that can contain or store programming for use by or in connection with an instruction execution system, apparatus, or device.

Software 850 can also be propagated within any transport medium for use by or in connection with an instruction execution system, apparatus, or device, such as those described above, that can fetch instructions associated with the software from the instruction execution system, apparatus, or device and execute the instructions. In the context of this disclosure, a transport medium can be any medium that can communicate, propagate, or transport programming for use by or in connection with an instruction execution system, apparatus, or device. The transport-readable medium can include, but is not limited to, an electronic, magnetic, optical, electromagnetic, or infrared wired or wireless propagation medium.

System 800 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

System 800 can implement any operating system suitable for operating on the network. Software 850 can be written in any suitable programming language, such as C, C++, Java, or Python. In various aspects, application software embodying the functionality of the present disclosure can be deployed in different configurations, such as in a client/server arrangement or through a Web browser as a Web-based application or Web service, for example.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A method for determining a turn-on voltage for a transistor, the method comprising:
applying a range of input voltages to a transistor and measuring resulting currents;
inputting the resulting currents into an on-state detection machine learning model trained to determine whether the transistor entered an on-state based on the resulting currents, wherein the on-state detection machine learning model outputs a classification indicating whether the transistor entered the on-state;
if the classification indicates the transistor entered the on-state, inputting the resulting currents into a turn-on region finding machine learning model trained to determine a current turn-on region of the inputted resulting currents, wherein the turn-on region finding machine learning model outputs a current turn-on region of the transistor; and
determining the turn-on voltage for the transistor based on the outputted current turn-on region of the transistor by identifying the turn-on voltage within the outputted current turn-on region.

2. The method of claim 1, wherein identifying the turn-on voltage within the outputted current turn-on region comprises correlating the outputted current turn-on region to the input voltages and determining an average voltage or midpoint voltage based on the input voltages correlated to the outputted current turn-on region.

3. The method of claim 1, wherein the turn-on region finding machine learning model outputs an array of identifiers in accordance with the inputted resulting currents.

4. The method of claim 1, wherein if the classification indicates the transistor did not enter the on-state, the resulting currents are not inputted into the turn-on region finding machine learning model and the turn-on voltage for the transistor is not determined.

5. The method of claim 1, wherein the transistor is a transistor like device.

6. The method of claim 1, wherein the transistor is a metal oxide field-effect transistor (MOSFET), a field-effect transistor (FET), or a single-electron transistor (SET).

7. The method of claim 1, wherein the classification from the on-state detection machine learning model is a binary label, wherein a first state of the binary label indicates the transistor entered the on-state and a second state of the binary label indicates the transistor did not enter the on-state.

8. The method of claim 1, comprising training the on-state detection machine learning model, comprising:
generating one or more transistor models;
inputting a range of labeled simulated voltages into the one or more transistor models and receiving labeled simulated currents from the one or more transistor models; and
training the on-state detection machine learning model based on the labeled simulated currents.

9. The method of claim 8, wherein the on-state detection machine learning model is further trained with labeled simulated voltages.

10. The method of claim 8, wherein the labeled simulated currents indicate a simulated transistor of the one or more transistor models entered the on-state or the labeled simulated currents indicate the simulated transistor of the one or more transistor models did not enter the on-state.

11. The method of claim 8, comprising training the turn-on region finding machine learning model, comprising:
labeling the current turn-on region of the labeled simulated currents; and
training the turn-on region finding machine learning model based on the labeled simulated currents comprising the labeled current turn-on region.

12. The method of claim 11, wherein labeling the current turn-on region of the labeled simulated currents comprises:
correlating each labeled simulated current of the labeled simulated currents to an identifier, wherein a first identifier represents the current turn-on region of a simulated transistor and a second identifier does not represent the current turn-on region of the simulated transistor.

13. A transistor system configured to turn on one or more transistors, the system comprising:
one or more voltage systems configured to apply a range of input voltages to the one or more transistors and configured to apply a turn-on voltage to each transistor of the one or more transistors;
one or more current systems configured to measure resulting currents from the one or more transistors;
a control system, comprising one or more processors, configured to:
turn on each transistor of the one or more transistors using the turn-on voltage for each transistor, wherein the turn-on voltage for each transistor has been determined by:
applying a range of input voltages to a transistor and measuring resulting currents;
inputting the resulting currents into an on-state detection machine learning model trained to determine whether the transistor entered an on-state based on the resulting currents, wherein the on-state detection machine learning model outputs a classification indicating whether the transistor entered the on-state;
if the classification indicates the transistor entered the on-state, inputting the resulting currents into a turn-on region finding machine learning model trained to determine a current turn-on region of the inputted resulting currents, wherein the turn-on region finding machine learning model outputs a current turn-on region of the transistor; and
determining the turn-on voltage for the transistor based on the outputted current turn-on region of the transistor by identifying the turn-on voltage within the outputted current turn-on region.

14. The transistor system of claim 13, wherein the control system is further configured to:
control the one or more voltage systems to apply the range of input voltages to the one or more transistors and to apply the turn-on voltage to each transistor of the one or more transistors; and
control the one or more current systems to measure the resulting currents from the one or more transistors.

15. The transistor system of claim 13, wherein the transistor is a transistor like device.

16. A method for determining turn-on voltages for one or more transistor like devices of a quantum device, the method comprising:
applying a range of input voltages to each transistor like device of the one or more transistor like devices and measuring resulting currents;
inputting the resulting currents into an on-state detection machine learning model trained to determine whether each transistor like device of the one or more transistor like devices entered an on-state based on the resulting currents, wherein the on-state detection machine learning model outputs a classification indicating whether each transistor like device of the one or more transistor like devices entered the on-state;
if the classification indicates one or more transistor like devices entered the on-state, inputting the resulting currents of each transistor like device of the one or more transistor like devices into a turn-on region finding machine learning model trained to determine a current turn-on region of the inputted resulting currents, wherein the turn-on region finding machine learning model outputs a current turn-on region of each transistor like device; and
determining the turn-on voltage for each transistor like device of the one or more transistor like devices based on the outputted current turn-on region of each transistor like device by identifying the turn-on voltage within the outputted current turn-on region of each transistor like device.
